(19) United States
(12) Patent Application Publication
(10) Pub. No.: US 2026/0031019 A1
(43) Pub. Date: Jan. 29, 2026

(54) DISPLAY PANEL, DISPLAY DEVICE, AND ELECTRONIC DEVICE INCLUDING THE SAME

(71) Applicant: Samsung Display Co., LTD., Yongin-si (KR)

(72) Inventors: HAE-KWAN SEO, Yongin-si (KR); BON-SEOG GU, Yongin-si (KR); JINYOUNG ROH, Yongin-si (KR); JAEKEUN LIM, Yongin-si (KR)

(21) Appl. No.: 19/030,801

(22) Filed: Jan. 17, 2025

(30) Foreign Application Priority Data
Jul. 24, 2024 (KR) 10-2024-0097697

(51) Int. Cl. G09G 3/32; G09G 3/3233

(52) U.S. Cl. CPC G09G 3/32; G09G 3/3233; G09G 2300/0819; G09G 2310/08; G09G 2330/021

(57) ABSTRACT

A display panel includes a data line, a first pixel for storing a first data voltage of the data line in a first capacitor in a first period of a data writing period, and a second pixel for storing a second data voltage of the data line in a second capacitor in a second period of the data writing period. The first pixel includes a first-first transistor located in a first path from the data line to the first capacitor, and configured to be turned on in response to a first signal during the first period of the data writing period. The second pixel includes a first-second transistor located in a second path from the data line to the second capacitor, and configured to be turned on in response to a second signal during the second period of the data writing period.

This application claims priority to Korean Patent Application No. 10-2024-0097697, filed on Jul. 24, 2024, and all the benefits accruing therefrom under 35 U.S.C. § 119, the content of which in its entirety is herein incorporated by reference.

### BACKGROUND

### 1. Technical Field

Embodiments relate generally to display devices, and more particularly to a display panel which performs a demultiplexing operation without a demultiplexer circuit, and a display device including the display panel.

### 2. Description of the Related Art

To reduce the number of output channels of a data driver, a demultiplexing driving technique has been developed which selectively connects each output channel to one of two or more data lines by using a demultiplexer circuit. The demultiplexer circuit may sequentially connect each output channel to the two or more data lines in a time-division manner within each horizontal time. Accordingly, a display device to which the demultiplexing driving technique is applied may have a smaller number of output channels than the number of data lines.

However, in a display device including the demultiplexer circuit, a size of a non-display region of a display panel may increase because the demultiplexer circuit is arranged in the non-display region, and power consumption may increase to perform a demultiplexing operation.

### SUMMARY

Some embodiments provide a display panel capable of performing a demultiplexing operation without a demultiplexer circuit.

Some embodiments provide a display device capable of performing a demultiplexing operation without a demultiplexer circuit.

According to some embodiments, there is provided a display panel including a data line, a first pixel configured to store a first data voltage of the data line in a first capacitor in a first period of a data writing period, and a second pixel configured to store a second data voltage of the data line in a second capacitor in a second period of the data writing period. The first pixel includes a first-first transistor located in a first path from the data line to the first capacitor, and configured to be turned on in response to a first signal during the first period of the data writing period. The second pixel includes a first-second transistor located in a second path from the data line to the second capacitor, and configured to be turned on in response to a second signal during the second period of the data writing period.

In embodiments, the first signal and the second signal may be a same signal having a first level in the first period of the data writing period and having a second level in the second period of the data writing period, and the first-first transistor and the first-second transistor may have different types from each other.

In embodiments, the first signal may have a first level in the first period of the data writing period, and may have a second level in the second period of the data writing period. The second signal may have the second level in the first period of the data writing period, and may have the first level in the second period of the data writing period. The first-first transistor and the first-second transistor may have a same type.

In embodiments, the first pixel may further include a second-first transistor connected in series with the first-first transistor in the first path, and configured to be turned on in response to a third signal during the data writing period. The second pixel may further include a second-second transistor connected in series with the first-second transistor in the second path, and configured to be turned on in response to the third signal during the data writing period.

In embodiments, the first signal and the second signal may be a same signal, and may be shifted by half of one horizontal time from the third signal.

In embodiments, the first signal may lead the third signal by half of one horizontal time, and the second signal may lag the third signal by half of one horizontal time.

In embodiments, one of the first pixel and the second pixel may further include a second transistor including a gate which receives a third signal, a first terminal connected to the data line, and a second terminal connected to both of the first-first transistor and the first-second transistor, and the other of the first pixel and the second pixel may not include a transistor corresponding to the second transistor.

In embodiments, the first pixel may include the first-first transistor including a gate which receives the first signal, a first terminal, and a second terminal, a second-first transistor including a gate which receives a third signal, a first terminal connected to the data line, and a second terminal connected to the first terminal of the first-first transistor, a third-first transistor including a gate connected to the second terminal of the first-first transistor, a first terminal which receives a first power supply voltage, and a second terminal, the first capacitor including a first electrode connected to the gate of the third-first transistor, and a second electrode connected to the first terminal of the third-first transistor, and a first light emitting element including an anode connected to the second terminal of the third-first transistor, and a cathode which receives a second power supply voltage. The second pixel may include the first-second transistor including a gate which receives the second signal, a first terminal, and a second terminal, the second-second transistor including a gate which receives the third signal, a first terminal connected to the data line, and a second terminal connected to the first terminal of the first-second transistor, a third-second transistor including a gate connected to the second terminal of the first-second transistor, a first terminal which receives the first power supply voltage, and a second terminal, the second capacitor including a first electrode connected to the gate of the third-second transistor, and a second electrode connected to the first terminal of the third-second transistor, and a second light emitting element including an anode connected to the second terminal of the third-second transistor, and a cathode which receives the second power supply voltage.

In embodiments, the first signal and the second signal may be a same demultiplexing signal having a first level in the first period of the data writing period and having a second level in the second period of the data writing period, and the third signal may be a writing signal having the first level in the data writing period. The first-first transistor, the second-first transistor, the second-second transistor, the third-first transistor and the third-second transistor may be P-type transistors, and the first-second transistor may be an N-type transistor.

In embodiments, the first signal and the second signal may be a same demultiplexing signal having a second level in the first period of the data writing period and having the first level in the second period of the data writing period, and the third signal may be a writing signal having the second level in the data writing period. The first-first transistor, the second-first transistor, the second-second transistor, the third-first transistor and the third-second transistor may be N-type transistors, and the first-second transistor may be a P-type transistor.

In embodiments, the first signal may be a first demultiplexing signal having a first level in the first period of the data writing period and having a second level in the second period of the data writing period, the second signal may be a second demultiplexing signal having the second level in the first period of the data writing period and having a first level in the second period of the data writing period, and the third signal may be a writing signal having the first level in the data writing period. The first-first transistor, the first-second transistor, the second-first transistor, the second-second transistor, the third-first transistor and the third-second transistor may be P-type transistors.

In embodiments, the first signal may be a first demultiplexing signal having a second level in the first period of the data writing period and having a first level in the second period of the data writing period, the second signal may be a second demultiplexing signal having the first level in the first period of the data writing period and having the second level in the second period of the data writing period, and the third signal may be a writing signal having the second level in the data writing period. The first-first transistor, the first-second transistor, the second-first transistor, the second-second transistor, the third-first transistor and the third-second transistor may be N-type transistors.

In embodiments, the first pixel may include the first-first transistor including a gate which receives the first signal, a first terminal, and a second terminal, a second-first transistor including a gate which receives a third signal, a first terminal connected to the data line, and a second terminal connected to the first terminal of the first-first transistor, a third-first transistor including a gate, a first terminal connected to the second terminal of the first-first transistor, and a second terminal, the first capacitor including a first electrode connected to the gate of the third-first transistor, and a second electrode which receives a first power supply voltage, a fourth-first transistor including a gate which receives the third signal, a first terminal connected to the second terminal of the third-first transistor, and a second terminal connected to the gate of the third-first transistor, a fifth-first transistor including a gate which receives a fourth signal, a first terminal connected to the gate of the third-first transistor, and a second terminal which receives an initialization voltage, a sixth-first transistor including a gate which receives a fifth signal, a first terminal which receives the first power supply voltage, and a second terminal connected to the first terminal of the third-first transistor, a seventh-first transistor including a gate which receives the fifth signal, a first terminal connected to the second terminal of the third-first transistor, and a second terminal, an eighth-first transistor including a gate which receives a sixth signal, a first terminal, and a second terminal which receives the initialization voltage, and a first light emitting element including an anode connected to the second terminal of the seventh-first transistor and the first terminal of the eighth-first transistor, and a cathode which receives a second power supply voltage. The second pixel may include a first-second transistor including a gate which receives the second signal, a first terminal, and a second terminal, a second-second transistor including a gate which receives the third signal, a first terminal connected to the data line, and a second terminal connected to the first terminal of the first-second transistor, a third-second transistor including a gate, a first terminal connected to the second terminal of the first-second transistor, and a second terminal, the second capacitor including a first electrode connected to the gate of the third-second transistor, and a second electrode which receives the first power supply voltage, a fourth-second transistor including a gate which receives the third signal, a first terminal connected to the second terminal of the third-second transistor, and a second terminal connected to the gate of the third-second transistor, a fifth-second transistor including a gate which receives the fourth signal, a first terminal connected to the gate of the third-second transistor, and a second terminal which receives the initialization voltage, a sixth-second transistor including a gate which receives the fifth signal, a first terminal which receives the first power supply voltage, and a second terminal connected to the first terminal of the third-second transistor, a seventh-second transistor including a gate which receives the fifth signal, a first terminal connected to the second terminal of the third-second transistor, and a second terminal, an eighth-second transistor including a gate which receives the sixth signal, a first terminal, and a second terminal which receives the initialization voltage, and a second light emitting element including an anode connected to the second terminal of the seventh-second transistor and the first terminal of the eighth-second transistor, and a cathode which receives the second power supply voltage.

In embodiments, the third signal may be a writing signal, the fourth signal may be an initialization signal, the fifth signal may be an emission signal, the sixth signal may be a bypass signal, and the first signal and the second signal may be the bypass signal. The first-first transistor and the first-second transistor may have different types from each other.

In embodiments, the third signal may be a writing signal, the fourth signal may be an initialization signal, the fifth signal may be an emission signal, the sixth signal may be a bypass signal, the first signal may be the bypass signal, and the second signal may be a bypass signal for a pixel row different from a pixel row including the first and second pixels. The first-first transistor and the first-second transistor may have a same type.

In embodiments, the third signal may be a writing signal, the fourth signal may be an initialization signal, the fifth signal may be an emission signal, the sixth signal may be a bypass signal, the first signal may be the bypass signal, and the second signal may be an initialization signal for a pixel row different from a pixel row including the first and second pixels. The first-first transistor and the first-second transistor may have a same type.

In embodiments, the first pixel may include the first-first transistor including a gate which receives the first signal, a first terminal connected to the data line, and a second terminal, a second-first transistor including a gate which receives a third signal, a first terminal connected to the second terminal of the first-first transistor, and a second terminal, a third-first transistor including a first gate connected to the second terminal of the second-first transistor, a first terminal, a second terminal and a second gate, the first capacitor including a first electrode connected to the first gate of the third-first transistor, and a second electrode connected to the second terminal and the second gate of the third-first transistor, a third capacitor including a first electrode which receives a first power supply voltage, and a second electrode connected to the second terminal and the second gate of the third-first transistor, a fourth-first transistor including a gate which receives a fourth signal, a first terminal which receives a reference voltage, and a second terminal connected to the first gate of the third-first transistor, a fifth-first transistor including a gate which receives a fifth signal, a first terminal which receives the first power supply voltage, and a second terminal connected to the first terminal of the third-first transistor, a sixth-first transistor including a gate which receives a sixth signal, a first terminal connected to the second terminal and the second gate of the third-first transistor, and a second terminal, a seventh-first transistor including a gate which receives a seventh signal, a first terminal, and a second terminal which receives an initialization voltage, and a first light emitting element including an anode connected to the second terminal of the sixth-first transistor and the first terminal of the seventh-first transistor, and a cathode which receives a second power supply voltage. The second pixel may include the first-second transistor including a gate which receives the second signal, a first terminal connected to the data line, and a second terminal, a second-second transistor including a gate which receives the third signal, a first terminal connected to the second terminal of the first-second transistor, and a second terminal, a third-second transistor including a first gate connected to the second terminal of the second-second transistor, a first terminal, a second terminal and a second gate, the second capacitor including a first electrode connected to the first gate of the third-second transistor, and a second electrode connected to the second terminal and the second gate of the third-second transistor, a fourth capacitor including a first electrode which receives the first power supply voltage, and a second electrode connected to the second terminal and the second gate of the third-second transistor, a fourth-second transistor including a gate which receives the fourth signal, a first terminal which receives the reference voltage, and a second terminal connected to the first gate of the third-second transistor, a fifth-second transistor including a gate which receives the fifth signal, a first terminal which receives the first power supply voltage, and a second terminal connected to the first terminal of the third-second transistor, a sixth-second transistor including a gate which receives the sixth signal, a first terminal connected to the second terminal and the second gate of the third-second transistor, and a second terminal, a seventh-second transistor including a gate which receives the seventh signal, a first terminal, and a second terminal which receives the initialization voltage, and a second light emitting element including an anode connected to the second terminal of the sixth-second transistor and the first terminal of the seventh-second transistor, and a cathode which receives the second power supply voltage.

In embodiments, the third signal may be a writing signal, the fourth signal may be a reference signal, the fifth signal may be a first emission signal, the sixth signal may be a second emission signal, the seventh signal may be an initialization signal, and the first signal and the second signal may be the initialization signal. The first-first transistor and the first-second transistor may have different types from each other.

In embodiments, a first light emitting element included in the first pixel and a second light emitting element included in the second pixel may be light emitting elements of a same color.

In embodiments, the first pixel may include a first pixel circuit including the first capacitor and the first-first transistor, and configured to generate a first driving current based on the first data voltage, and a first light emitting element connected to the first pixel circuit, and configured to emit light based on the first driving current. The second pixel may include a second pixel circuit including the second capacitor and the first-second transistor, and configured to generate a second driving current based on the second data voltage, and a second light emitting element including an anode extension, connected to the second pixel circuit through the anode extension, and configured to emit light based on the second driving current.

In embodiments, the first pixel may include a first pixel circuit located in a first column, and a first red light emitting element located in the first column and a second column, and the second pixel may include a second pixel circuit located in the second column, and a second red light emitting element located in a fourth column and a fifth column. The display panel may further include a third pixel including a third pixel circuit located in a third column, and a first green light emitting element located in the first column and the second column, a fourth pixel including a fourth pixel circuit located in the fourth column, and a second green light emitting element located in the fourth column and the fifth column, a fifth pixel including a fifth pixel circuit located in the fifth column, and a first blue light emitting element located in the second column and the third column, and a sixth pixel including a sixth pixel circuit located in a sixth column, and a second blue light emitting element located in the fifth column and the sixth column. The second red light emitting element located in the fourth column and the fifth column may be connected to the second pixel circuit located in the second column through an anode extension of the second red light emitting element, the first green light emitting element located in the first column and the second column may be connected to the third pixel circuit located in the third column through an anode extension of the first green light emitting element, and the first blue light emitting element located in the second column and the third column may be connected to the fifth pixel circuit located in the fifth column through an anode extension of the first blue light emitting element.

In embodiments, the data line may be a first data line connected to the first pixel circuit and the second pixel circuit, located between the first column and the second column, and transferring the first and second data voltages for the first and second red light emitting elements. The display panel may further include a second data line located between the third column and the fourth column, connected to the third pixel circuit and the fourth pixel circuit, and transferring data voltages for the first and second green light emitting elements, and a third data line located between the fifth column and the sixth column, connected to the fifth pixel circuit and the sixth pixel circuit, and transferring data voltages for the first and second blue light emitting elements.

In embodiments, the first pixel may include a first pixel circuit located in a second column, and a first red light emitting element located in a first column and the second column, and the second pixel may include a second pixel circuit located in a third column, and a second red light emitting element located in a fourth column and a fifth column. The display panel may further include a third pixel including a third pixel circuit located in the first column, and a first green light emitting element located in the first column and the second column, a fourth pixel including a fourth pixel circuit located in a sixth column, and a second green light emitting element located in the fourth column and the fifth column, a fifth pixel including a fifth pixel circuit located in the fourth column, and a first blue light emitting element located in the second column and the third column, and a sixth pixel including a sixth pixel circuit located in the fifth column, and a second blue light emitting element located in the fifth column and the sixth column. The second red light emitting element located in the fourth column and the fifth column may be connected to the second pixel circuit located in the third column through an anode extension of the second red light emitting element, the second green light emitting element located in the fourth column and the fifth column may be connected to the fourth pixel circuit located in the sixth column through an anode extension of the second green light emitting element, and the first blue light emitting element located in the second column and the third column may be connected to the fifth pixel circuit located in the fourth column through an anode extension of the first blue light emitting element.

In embodiments, the data line may be a second data line connected to the first pixel circuit and the second pixel circuit, located between the second column and the third column, and transferring the first and second data voltages for the first and second red light emitting elements. The display panel may further include a first data line located adjacent to the first column, connected to the third pixel circuit, and transferring a data voltage for the first green light emitting element, a third data line located between the fourth column and the fifth column, connected to the fifth pixel circuit and the sixth pixel circuit, and transferring data voltages for the first and second blue light emitting elements, and a fourth data line located adjacent to the sixth column, connected to the fourth pixel circuit, and transferring a data voltage for the second green light emitting element.

In embodiments, the first pixel may include a first pixel circuit located in a first row and a first column, and a first red light emitting element located in the first row and the first column, and the second pixel may include a second pixel circuit located in the first row and a second column, and a second red light emitting element located in a second row and the second and third columns. The display panel may further include a third pixel including a third pixel circuit located in the first row and the third column, and a first blue light emitting element located in the first row and the second and third columns, a fourth pixel including a fourth pixel circuit located in the first row and a fourth column, and a second blue light emitting element located in the second row and the fourth and fifth columns, a fifth pixel including a fifth pixel circuit located in the second row and the first column, and a first green light emitting element located in the second row and the first and second columns, a sixth pixel including a sixth pixel circuit located in the second row and the second column, and a second green light emitting element located in a third row and the first and second columns, a seventh pixel including a seventh pixel circuit located in the second row and the third column, and a third green light emitting element located in the second row and the third and fourth columns, and an eighth pixel circuit located in the second row and the fourth column, and a fourth green light emitting element located in the third row and the third and fourth columns.

In embodiments, the data line may be a first data line connected to the first, second, fifth and sixth pixel circuits, located between the first column and the second column, transferring the first and second data voltages for the first and second red light emitting elements in the data writing period, and transferring data voltages for the first and second green light emitting elements in a second data writing period after the data writing period. The display panel may further include a second data line located between the third column and the fourth column, connected to the third, fourth, seventh and eighth pixel circuits, transferring data voltages for the first and second blue light emitting elements in the data writing period, and transferring data voltages for the third and fourth green light emitting elements in the second data writing period.

According to some embodiments, there is provided an electronic device including a display panel; and a power supply configured to provide power to the display panel. The display panel includes: a first data line, a second data line, a first pixel configured to store a first data voltage of the first data line in a first capacitor in a first period of a data writing period, and a second pixel configured to store a second data voltage of the second data line in a second capacitor in a second period of the data writing period. The first pixel includes a first-first transistor located in a first path from the first data line to the first capacitor, and configured to be turned on in response to a first signal during the first period of the data writing period, and the second pixel includes a first-second transistor located in a second path from the second data line to the second capacitor, and configured to be turned on in response to a second signal during the second period of the data writing period.

According to some embodiments, there is provided a display panel including a data line, a first pixel configured to store a first data voltage of the data line in a first capacitor in a portion of a data writing period, and a second pixel configured to store a second data voltage of the data line in a second capacitor in an entire period of the data writing period. The first pixel includes a first transistor located in a path from the data line to the first capacitor, configured to be turned on in response to a first signal during the portion of the data writing period, and configured to be turned off a remaining period of the data writing period.

In embodiments, the first pixel may further include a second-first transistor connected in series with the first transistor in the path, and configured to be turned on in response to a second signal during the data writing period, and the second pixel may include the second capacitor, and a second-second transistor directly connected to the data line, and configured to be turned on in response to the second signal during the data writing period.

According to some embodiments, there is provided a display device including a display panel including a data line, a first pixel configured to store a first data voltage of the data line in a first capacitor in a first period of a data writing period, and a second pixel configured to store a second data voltage of the data line in a second capacitor in a second period of the data writing period, a scan driver configured to provide a first signal, a second signal and a writing signal having an on-level during the data writing period to the first pixel and the second pixel, a data driver configured to provide the first data voltage and the second data voltage to the first pixel and the second pixel through the data line, and a controller configured to control the scan driver and the data driver. The first pixel includes a first-first transistor located in a first path from the data line to the first capacitor, and configured to be turned on in response to the first signal during the first period of the data writing period, and the second pixel includes a first-second transistor located in a second path from the data line to the second capacitor, and configured to be turned on in response to the second signal during the second period of the data writing period.

As described above, in a display panel and a display device according to embodiments, a first pixel may include a first-first transistor that is turned on to store a first data voltage of a data line in a first capacitor of the first pixel in response to a first signal during a first period of a data writing period, and a second pixel may include a first-second transistor that is turned on to store a second data voltage of the data line in a second capacitor of the second pixel in response to a second signal during a second period of the data writing period. Accordingly, in the display panel and the display device according to embodiments, a demultiplexing operation may be performed without a demultiplexer circuit, a size of a non-display region of the display panel may be reduced, and power consumption of the display device may be effectively reduced.

### BRIEF DESCRIPTION OF THE DRAWINGS

Illustrative, non-limiting embodiments will be more clearly understood from the following detailed description taken in conjunction with the accompanying drawings.

FIG. 1 is a diagram illustrating a portion of a first pixel and a portion of a second pixel included in a display panel according to embodiments.

FIG. 2 is a timing diagram for describing an example of an operation of a first pixel and a second pixel illustrated in FIG. 1.

FIG. 3 is a circuit diagram illustrating a first pixel and a second pixel included in a display panel according to embodiments.

FIG. 4 is a timing diagram for describing an example of an operation of a first pixel and a second pixel illustrated in FIG. 3.

FIG. 5 is a circuit diagram illustrating a first pixel and a second pixel included in a display panel according to embodiments.

FIG. 6 is a timing diagram for describing an example of an operation of a first pixel and a second pixel illustrated in FIG. 5.

FIG. 7 is a circuit diagram illustrating a first pixel and a second pixel included in a display panel according to embodiments.

FIG. 8 is a timing diagram for describing an example of an operation of a first pixel and a second pixel illustrated in FIG. 7.

FIG. 9 is a circuit diagram illustrating a first pixel and a second pixel included in a display panel according to embodiments.

FIG. 10 is a timing diagram for describing an example of an operation of a first pixel and a second pixel illustrated in FIG. 9.

FIG. 11 is a diagram illustrating a portion of a first pixel and a portion of a second pixel included in a display panel according to embodiments.

FIG. 12 is a timing diagram for describing an example of an operation of a first pixel and a second pixel illustrated in FIG. 11.

FIG. 13 is a circuit diagram illustrating a first pixel and a second pixel included in a display panel according to embodiments.

FIG. 14 is a timing diagram for describing an example of an operation of a first pixel and a second pixel illustrated in FIG. 13.

FIG. 15 is a circuit diagram illustrating a first pixel and a second pixel included in a display panel according to embodiments.

FIG. 16 is a timing diagram for describing an example of an operation of a first pixel and a second pixel illustrated in FIG. 15.

FIG. 17 is a circuit diagram illustrating a first pixel and a second pixel included in a display panel according to embodiments.

FIG. 18 is a timing diagram for describing an example of an operation of a first pixel and a second pixel illustrated in FIG. 17.

FIG. 19 is a circuit diagram illustrating a first pixel and a second pixel included in a display panel according to embodiments.

FIG. 20 is a timing diagram for describing an example of an operation of a first pixel and a second pixel illustrated in FIG. 19.

FIG. 21 is a circuit diagram illustrating a first pixel and a second pixel included in a display panel according to embodiments.

FIG. 22 is a circuit diagram illustrating a first pixel and a second pixel included in a display panel according to embodiments.

FIG. 23 is a circuit diagram illustrating a first pixel and a second pixel included in a display panel according to embodiments.

FIG. 24 is a timing diagram for describing an example of an operation of a first pixel and a second pixel illustrated in FIG. 23.

FIG. 25 is a diagram illustrating a display panel according to embodiments.

FIG. 26 is a circuit diagram illustrating a first pixel and a second pixel included in a display panel according to embodiments.

FIG. 27 is a diagram illustrating a display panel including a first pixel and a second pixel illustrated in FIG. 26.

FIG. 28 is a diagram illustrating a portion of a display panel according to embodiments.

FIG. 29 is a timing diagram for describing an example of data voltages provided to a display panel illustrated in FIG. 28.

FIG. 30 is a diagram illustrating a portion of a display panel according to embodiments.

FIG. 31 is a timing diagram for describing an example of data voltages provided to a display panel illustrated in FIG. 30.

FIG. 32 is a diagram illustrating a portion of a display panel according to embodiments.

FIG. 33 is a timing diagram for describing an example of data voltages provided to a display panel illustrated in FIG. 32.

FIG. 34 is a block diagram illustrating a display device according to embodiments.

FIG. 35 is a block diagram illustrating an electronic device including a display device according to embodiments.

### DESCRIPTION OF EMBODIMENTS

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third,” “first-first,”, “first-second,” “second-first,” “second-second,” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The embodiments are described more fully hereinafter with reference to the accompanying drawings. Like or similar reference numerals refer to like or similar elements throughout.

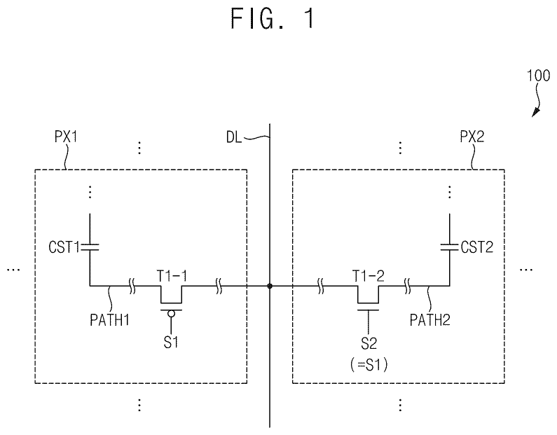

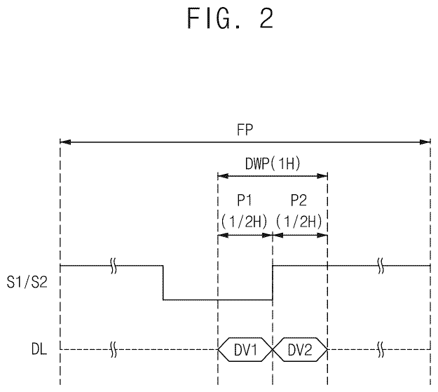

FIG. 1 is a diagram illustrating a portion of a first pixel and a portion of a second pixel included in a display panel according to embodiments, and FIG. 2 is a timing diagram for describing an example of an operation of a first pixel and a second pixel illustrated in FIG. 1.

Referring to FIG. 1, a display panel 100 according to embodiments may include a data line DL, a first pixel PX1 connected to the data line DL, and a second pixel PX2 connected to the data line DL. Although two pixels PX1 and PX2 included in the display panel 100 are illustrated in FIG. 1, the display panel 100 according to embodiments may include a plurality of pixels.

The first pixel PX1 may include a first capacitor CST1, and a first-first transistor T1-1 located in a first path PATH1 from the data line DL to the first capacitor CST1, and the second pixel PX2 may include a second capacitor CST2, and a first-second transistor T1-2 located in a second path PATH2 from the data line DL to the second capacitor CST2. The first-first transistor T1-1 may be turned on in response to a first signal S1 in a first period within a data writing period for a pixel row in which the first and second pixels PX1 and PX2 are arranged, and the first-second transistor T1-2 may be turned on in response to a second signal S2 in a second period within the data writing period. Further, a first data voltage for the first pixel PX1 may be provided to the data line DL in the first period of the data writing period, and a second data voltage for the second pixel PX2 may be provided to the data line DL in the second period of the data writing period. Accordingly, the first pixel PX1 may store the first data voltage in the first capacitor CST1 in the first period of the data writing period, and the second pixel PX2 may store the first data voltage in the second capacitor CST2 in the second period of the data writing period. Therefore, the display panel 100 according to embodiments may perform a demultiplexing operation by using the first transistor T1-1 and the second transistor T1-2 included in the first pixel PX1 and the second pixel PX2, respectively, without a demultiplexer circuit.

In some embodiments, as illustrated in FIGS. 1 and 2, the first-first transistor T1-1 and the first-second transistor T1-2 may have different types (e.g., P-type, N-type) from each other, and the first signal S1 and the second signal S2 may be the same signal having a first level (e.g., a low level) in the first period P1 of the data writing period DWP and having a second level (e.g., a high level) in the second period P2 of the data writing period DWP. Here, the data writing period DWP may be a period in which a data writing operation is performed on a pixel row in which the first and second pixels PX1 and PX2 are arranged, and may be a period in which a writing signal applied to the first and second pixels PX1 and PX2 has an on-level. Further, in some embodiments, the data writing period DWP may have a time length of about 1 horizontal time 1H. The first period P1 may be the first half of the data writing period DWP, and may have a time length of about ½ horizontal time ½H. The second period P2 may be the latter half of the data writing period DWP, and may have a time length of about ½ horizontal time ½H. Here, 1 horizontal time 1H may be a time allocated to each pixel row of the display panel 100, and may be determined by dividing one frame period by the number of pixel rows of the display panel 100.

For example, as illustrated in FIGS. 1 and 2, the first-first transistor T1-1 may be a P-type transistor (e.g., a P-type metal oxide semiconductor (“PMOS”) transistor), and the first-second transistor T1-2 may be an N-type transistor (e.g., an N-type metal oxide semiconductor (“NMOS”) transistor). Further, the first signal S1 and the second signal S2 may have the low level in the first period P1 of the data writing period DWP, and may have the high level in the second period P2 of the data writing period DWP. Thus, in the first period P1 of the data writing period DWP, the first-first transistor T1-1 may be turned on, the first-second transistor T1-2 may be turned off, the first data voltage DV1 for the first pixel PX1 may be transferred from the data line DL to the first capacitor CST1 through the first-first transistor T1-1, and the first capacitor CST1 of the first pixel PX1 may store the first data voltage DV1. Further, in the second period P2 of the data writing period DWP, the first-first transistor T1-1 may be turned off, the first-second transistor T1-2 may be turned on, the second data voltage DV2 for the second pixel PX2 may be transferred from the data line DL to the second capacitor CST2 through the first-second transistor T1-2, and the second capacitor CST2 of the second pixel PX2 may store the second data voltage DV2.

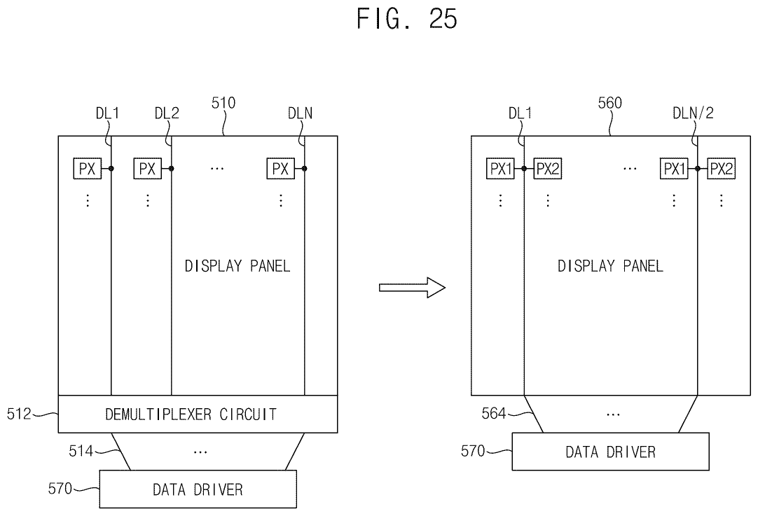

As described above, the display panel 100 according to embodiments may perform demultiplexing operation using the first and second transistors T1-1 and T1-2 respectively included in the first and second pixels PX1 and PX2 without a demultiplexer circuit. Accordingly, a size of a non-display region of the display panel 100 may be reduced compared with a size of a non-display area of a conventional display panel including the demultiplexer circuit. Further, in the display panel 100 according to embodiments, since power for driving the demultiplexer circuit is not consumed, the power consumption of the display panel 100 according to embodiments and the power consumption of a display device including the display panel 100 may be reduced. Further, as described below with reference to FIG. 25, the number of data lines of the display panel 100 according to embodiments may be reduced (e.g., to half the number of data lines of the conventional display panel).

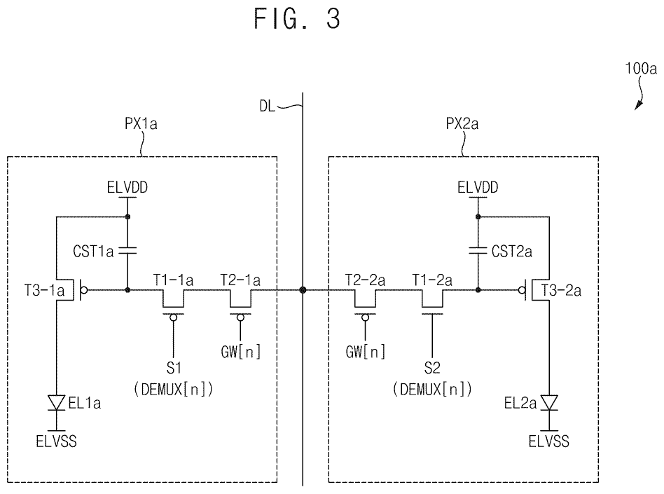

FIG. 3 is a circuit diagram illustrating a first pixel and a second pixel included in a display panel according to embodiments.

Referring to FIG. 3, a display panel 100a according to embodiments may include a data line DL, a first pixel PX1a connected to the data line DL, and a second pixel PX2a connected to the data line DL. The first pixel PX1a may include a first-first transistor T1-1a, a second-first transistor T2-1a, a third-first transistor T3-1a, a first capacitor CST1a and a first light emitting element EL1a, and the second pixel PX2a may include a first-second transistor T1-2a, a second-second transistor T2-2a, a third-second transistor T3-2a, a second capacitor CST2a and a second light emitting element EL2a.

The first-first transistor T1-1a may be turned on in response to a first signal S1, and the first-second transistor T1-2a may be turned on in response to a second signal S2. In some embodiments, the first-first transistor T1-1a and the first-second transistor T1-2a may have different types from each other, and the first signal S1 and the second signal S2 may be the same demultiplexing signal DEMUX[n]. For example, the first-first transistor T1-1a may be a P-type transistor that is turned on in response to the demultiplexing signal DEMUX[n] having a first level (e.g., a low level), and the first-second transistor T1-2a may be an N-type transistor that is turned on in response to the demultiplexing signal DEMUX[n] having a second level (e.g., a high level). In some embodiments, the first-first transistor T1-1a may include a gate which receives the demultiplexing signal DEMUX[n], a first terminal connected to the second-first transistor T2-1a, and a second terminal connected to the third-first transistor T3-1a and the first capacitor CST1a, and the first-second transistor T1-2a may include a gate which receives the demultiplexing signal DEMUX[n], a first terminal connected to the second-second transistor T2-2a, and a second terminal connected to the third-second transistor T3-2a and the second capacitor CST2a.

The second-first transistor T2-1a may be connected in series with the first-first transistor T1-1a in a first path from the data line DL to the first capacitor CST1a, and the second-second transistor T2-2a may be connected in series with the first-second transistor T1-2a in a first path from the data line DL to the second capacitor CST2a. Although FIG. 3 illustrates an example in which the second-first transistor T2-1a is directly connected to the data line DL and the first-first transistor T1-1a is connected to the data line DL through the second-first transistor T2-1a, in other embodiments, the first-first transistor T1-1a may be directly connected to the data line DL and the second-first transistor T2-1a may be connected to the data line DL through the first-first transistor T1-1a. Further, FIG. 3 illustrates the example in which the second-second transistor T2-2a is directly connected to the data line DL and the first-second transistor T1-2a is connected to the data line DL through the second-second transistor T2-2a, in other embodiments, the first-second transistor T1-2a may be directly connected to the data line DL and the second-second transistor T2-2a may be connected to the data line DL through the first-second transistor T1-2a.

The second-first transistor T2-1a may be turned on in response to a third signal, or a writing signal GW[n], and the second-second transistor T2-2a may be turned on in response to the third signal, or the writing signal GW[n]. Further, the writing signal GW[n] may have an on-level or the first level (e.g., the low level) during a data writing period, and the second-first transistor T2-1a and the second-second transistor T2-2a may be turned on during the data writing period. In some embodiments, the second-first transistor T2-1a may include a gate which receives the writing signal GW[n], a first terminal connected to the data line DL, and a second terminal connected to the first terminal of the first-first transistor T1-1a, and the second-second transistor T2-2a may include a gate which receives the writing signal GW[n], a first terminal connected to the data line DL, and a second terminal connected to the first terminal of the first-second transistor T1-2a.

The third-first transistor T3-1a may generate a first driving current based on a first data voltage stored in the first capacitor CST1a, and the third-second transistor T3-2a may generate a second driving current based on a second data voltage stored in the second capacitor CST2a. In some embodiments, the third-first transistor T3-1a may include a gate connected to the first capacitor CST1a and the second terminal of the first-first transistor T1-1a, a first terminal which receives a first power supply voltage ELVDD (e.g., a high power supply voltage), and a second terminal connected to the first light emitting element EL1a, and the third-second transistor T3-2a may include a gate connected to the second capacitor CST2a and the second terminal of the first-second transistor T1-2a, a first terminal which receives the first power supply voltage ELVDD, and a second terminal connected to the second light emitting element EL2a.

The first capacitor CST1a may store the first data voltage transferred from the data line DL through the first-first transistor T1-1a and the second-first transistor T2-1a, and the second capacitor CST2a may store the second data voltage transferred from the data line DL through the first-second transistor T1-2a and the second-second transistor T2-2a. In some embodiments, the first capacitor CST1a may include a first electrode connected to the gate of the third-first transistor T3-1a, and a second electrode connected to the first terminal (e.g., a source) of the third-first transistor T3-1a, and the second capacitor CST2a may include a first electrode connected to the gate of the third-second transistor T3-2a, and a second electrode connected to the first terminal (e.g., the source) of the third-second transistor T3-2a.

The first light emitting element EL1a may emit light based on the first driving current generated by the third-first transistor T3-1a, and the second light emitting element EL2a may emit light based on the second driving current generated by the third-second transistor T3-2a. In some embodiments, each of the first and second light emitting elements EL1a and EL2a may be an organic light emitting diode (“OLED”), but is not limited thereto. In other embodiments, each of the first and second light emitting elements EL1a and EL2a may be a nano light emitting diode (“NED”), a quantum dot (“QD”) light emitting diode, a micro light emitting diode, an inorganic light emitting diode, or any other suitable light emitting element. Further, in some embodiments, the first light emitting element EL1a may include an anode connected to the second terminal of the third-first transistor T3-1a, and a cathode which receives a second power supply voltage ELVSS (e.g., a low power supply voltage), and the second light emitting element EL2a may include an anode connected to the second terminal of the third-second transistor T3-2a, and a cathode which receives the second power supply voltage ELVSS.

In some embodiments, as illustrated in FIG. 3, the first-first transistor T1-1a, the second-first transistor T2-1a, the second-second transistor T2-2a, the third-first transistor T3-1a, and the third-second transistor T3-2a may be P-type transistors, and the first-second transistor T1-2a may be an N-type transistor. For example, the first-first, second-first, second-second, third-first and third-second transistors T1-1a, T2-1a, T2-2a, T3-1a and T3-2a may be PMOS transistors, and the first-second transistor T1-2a may be an NMOS transistor, but is not limited thereto. In other embodiments, each of the first-first, first-second, second-first, second-second, third-first and third-second transistors T1-1a, T1-2a, T2-1a, T2-2a, T3-1a and T3-2a may be any type of transistor, but the first-first transistor T1-1a and the first-second transistor T1-2a may be different types of transistors from each other.

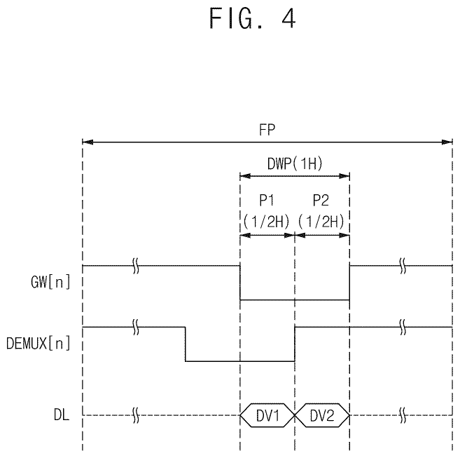

FIG. 4 is a timing diagram for describing an example of an operation of a first pixel and a second pixel illustrated in FIG. 3.

Referring to FIGS. 3 and 4, a frame period FP may include the data writing period DWP in which the first and second data voltages DV1 and DV2 are provided or written to the first and second pixels PX1a and PX2a. The data writing period DWP may have a time length of about 1 horizontal time 1H.

In a first period P1 of the data writing period DWP, the first and second signals S1 and S2, or the demultiplexing signal DEMUX[n] may have the low level, the third signal, or the writing signal GW[n] may have the low level, and the first data voltage DV1 for the first pixel PX1a may be applied to the data line DL. Thus, in the first period P1 of the data writing period DWP, the first-first transistor T1-1a and the second-first transistor T2-1a may be turned on, and the first capacitor CST1a may store the first data voltage DV1 transferred from the data line DL through the first-first transistor T1-1a and the second-first transistor T2-1a. Further, in the first period P1 of the data writing period DWP, although the second-second transistor T2-2a is turned on, the first-second transistor T1-2a may be turned off, and thus the second capacitor CST2a may be electrically disconnected from the data line DL.

In a second period P2 of the data writing period DWP, the demultiplexing signal DEMUX[n] may have the high level, the writing signal GW[n] may have the low level, and the second data voltage DV2 for the second pixel PX2a may be applied to the data line DL. Thus, in the second period P2 of the data writing period DWP, the first-second transistor T1-2a and the second-second transistor T2-2a may be turned on, and the second capacitor CST2a may store the second data voltage DV2 transferred from the data line DL through the first-second transistor T1-2a and the second-second transistor T2-2a. Further, in the second period P2 of the data writing period DWP, although the second-first transistor T2-1a is turned on, the first-first transistor T1-1a may be turned off, and thus the first capacitor CST1a may be electrically disconnected from the data line DL. Accordingly, the display panel 100a may perform a demultiplexing operation without a separate demultiplexer circuit.

In some embodiments, the first and second signals S1 and S2, or the demultiplexing signal DEMUX[n] may be shifted by about ½ horizontal time ½H from the third signal, or the writing signal GW[n]. For example, as illustrated in FIG. 4, the demultiplexing signal DEMUX[n] may lead the writing signal GW[n] by about ½ horizontal time ½H.

The third-first transistor T3-1a may generate the first driving current based on the first data voltage DV1 stored in the first capacitor CST1a, and the first light emitting element EL1a may emit light based on the first driving current. Further, the third-second transistor T3-2a may generate the second driving current based on the second data voltage DV2 stored in the second capacitor CST2a, and the second light emitting element EL2a may emit light based on the second driving current.

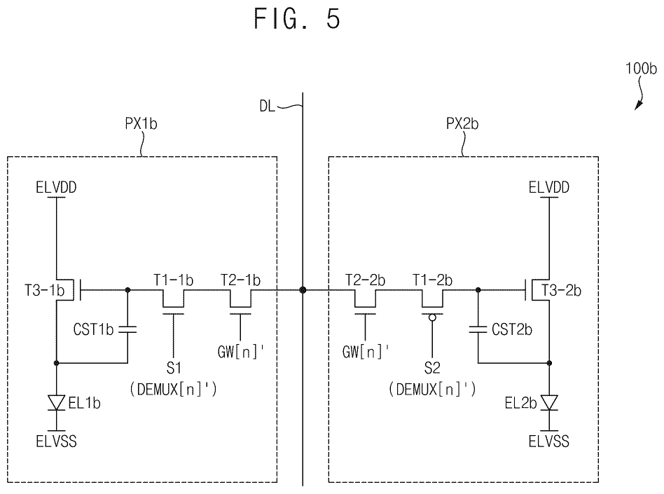

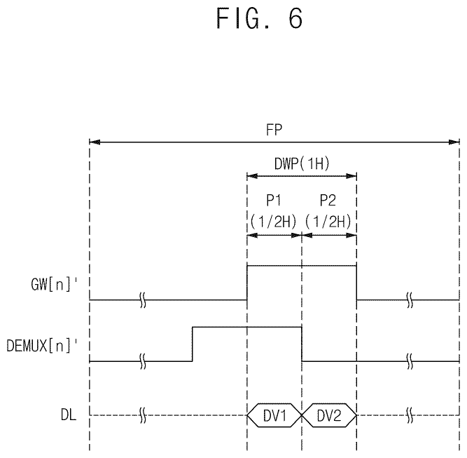

FIG. 5 is a circuit diagram illustrating a first pixel and a second pixel included in a display panel according to embodiments, and FIG. 6 is a timing diagram for describing an example of an operation of a first pixel and a second pixel illustrated in FIG. 5.

Referring to FIG. 5, a display panel 100b according to embodiments may include a data line DL, a first pixel PX1b and a second pixel PX2b. The first pixel PX1b may include a first-first transistor T1-1b, a second-first transistor T2-1b, a third-first transistor T3-1b, a first capacitor CST1b and a first light emitting element EL1b, and the second pixel PX2b may include a first-second transistor T1-2b, a second-second transistor T2-2b, a third-second transistor T3-2b, a second capacitor CST2b and a second light emitting element EL2b. The display panel 100b of FIG. 5 may have substantially the same configuration and substantially the same operation as a display panel 100a of FIG. 3, except that the first-first, second-first, second-second, third-first and third-second transistors T1-1b, T2-1b, T2-2b, T3-1b and T3-2b are N-type transistors and the first-second transistor T1-2b is a P-type transistor.

The first-first and first-second transistors T1-1b and T1-2b may receive the first and second signals S1 and S2, and the first and second signals S1 and S2 may be the same demultiplexing signal DEMUX[n]′. As illustrated in FIG. 6, the demultiplexing signal DEMUX[n]′ may have a high level in a first period P1 of a data writing period DWP, and may have a low level in a second period P2 of the data writing period DWP. Further, the second-first and second-second transistors T2-1b and T2-2b may receive a third signal, or a writing signal GW[n]′. As illustrated in FIG. 6, the writing signal GW[n]′ may have a high level during the data writing period DWP. Thus, in the first period P1 of the data writing period DWP, the first-first and second-first transistors T1-1b and T2-1b may be turned on, and a first data voltage DV1 may be stored in the first capacitor CST1b. Further, in the second period P2 of the data writing period DWP, the first-second and second-second transistors T1-2b and T2-2b may be turned on, and a second data voltage DV2 may be stored in the second capacitor CST2b. Accordingly, the display panel 100b may perform a demultiplexing operation without a separate demultiplexer circuit.

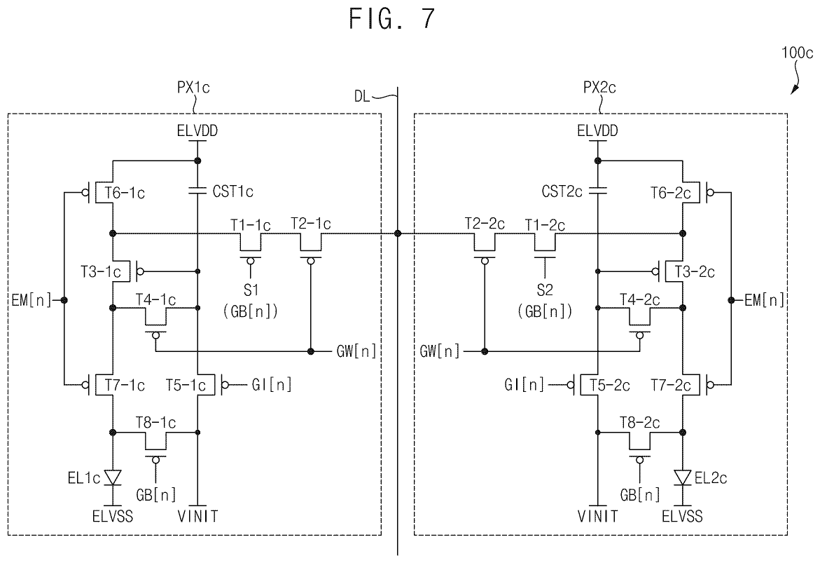

FIG. 7 is a circuit diagram illustrating a first pixel and a second pixel included in a display panel according to embodiments.

Referring to FIG. 7, a display panel 100c according to embodiments may include a data line DL, a first pixel PX1c and a second pixel PX2c. The first pixel PX1c may include a first-first transistor T1-1c, a second-first transistor T2-1c, a third-first transistor T3-1c, a first capacitor CST1c, a fourth-first transistor T4-1c, a fifth-first transistor T5-1c, a sixth-first transistor T6-1c, a seventh-first transistor T7-1c, an eighth-first transistor T8-1c and a first light emitting element EL1c, and the second pixel PX2c may include a first-second transistor T1-2c, a second-second transistor T2-2c, a third-second transistor T3-2c, a second capacitor CST2c, a fourth-second transistor T4-2c, a fifth-second transistor T5-2c, a sixth-second transistor T6-2c, a seventh-second transistor T7-2c, an eighth-second transistor T8-2c and a second light emitting element EL2c.

The first-first transistor T1-1c and the first-second transistor T1-2c may receive a first signal S1 and a second signal S2, respectively. In some embodiments, the first-first transistor T1-1c and the first-second transistor T1-2c may have different types from each other, and the first signal S1 and the second signal S2 may be the same bypass signal GB[n]. Further, the first-first transistor T1-1c may be located in a first path from the data line DL to the first capacitor CST1c, and the first-second transistor T1-2c may be located in a second path from the data line DL to the second capacitor CST2c.

In some embodiments, as illustrated in FIG. 7, the first-first transistor T1-1c may be located adjacent to the second-first transistor T2-1c, and the first-second transistor T1-2c may be located adjacent to the second-second transistor T2-2c. For example, the first-first transistor T1-1c may include a gate which receives the bypass signal GB[n], a first terminal connected to the second-first transistor T2-1c, and a second terminal connected to the third-first transistor T3-1c and the sixth-first transistor T6-1c, and the first-second transistor T1-2c may include a gate which receives the bypass signal GB[n], a first terminal connected to the second-second transistor T2-2c, and a second terminal connected to the third-second transistor T3-2c and the sixth-second transistor T6-2c.

In other embodiments, although not illustrated in FIG. 7, the first-first transistor T1-1c may be located adjacent to the fourth-first transistor T4-1c, and the first-second transistor T1-2c may be located adjacent to the fourth-second transistor T4-2c. For example, the first-first transistor T1-1c may be connected in series with the fourth-first transistor T4-1c between a gate of the third-first transistor T3-1c and a second terminal of the third-first transistor T3-1c, and the first-second transistor T1-2c may be connected in series with the fourth-second transistor T4-2c between a gate of the third-second transistor T3-2c and a second terminal of the third-second transistor T3-2c.

The second-first transistor T2-1c may be turned on in response to a third signal, or a writing signal GW[n], and the second-second transistor T2-2c may be turned on in response to the third signal, or the writing signal GW[n]. In some embodiments, the second-first transistor T2-1c may include a gate which receives the writing signal GW[n], a first terminal connected to the data line DL, and a second terminal connected to the first terminal of the first-first transistor T1-1c, and the second-second transistor T2-2c may include a gate which receives the writing signal GW[n], a first terminal connected to the data line DL, and a second terminal connected to the first terminal of the first-second transistor T1-2c.

The third-first transistor T3-1c may generate a first driving current based on a first data voltage stored in the first capacitor CST1c, and the third-second transistor T3-2c may generate a second driving current based on a second data voltage stored in the second capacitor CST2c. In some embodiments, the third-first transistor T3-1c may include a gate connected to the first capacitor CST1c, a first terminal connected to the second terminal of the first-first transistor T1-1c and the sixth-first transistor T6-1c, and a second terminal connected to the fourth-first transistor T4-1c and the seventh-first transistor T7-1c, and the third-second transistor T3-2c may include a gate connected to the second capacitor CST2c, a first terminal connected to the second terminal of the first-second transistor T1-2c and the sixth-second transistor T6-2c, and a second terminal connected to the fourth-second transistor T4-2c and the seventh-second transistor T7-2c.

The first capacitor CST1c may store the first data voltage transferred from the data line DL through the first-first transistor T1-1c, the second-first transistor T2-1c, the third-first transistor T3-1c and the fourth-first transistor T4-1c, and the second capacitor CST2c may store the second data voltage transferred from the data line DL through the first-second transistor T1-2c, the second-second transistor T2-2c, the third-second transistor T3-2c and the fourth-second transistor T4-2c. In some embodiments, the first capacitor CST1c may include a first electrode connected to the gate of the third-first transistor T3-1c, and a second electrode which receives a first power supply voltage ELVDD, and the second capacitor CST2c may include a first electrode connected to the gate of the third-second transistor T3-2c, and a second electrode which receives the first power supply voltage ELVDD.

The fourth-first transistor T4-1c may diode-connect the third-first transistor T3-1c in response to the third signal, or the writing signal GW[n], and the fourth-second transistor T4-2c may diode-connect the third-second transistor T3-2c in response to the third signal, or the writing signal GW[n]. In some embodiments, the fourth-first transistor T4-1c may include a gate which receives the writing signal GW[n], a first terminal connected to the second terminal of the third-first transistor T3-1c, and a second terminal connected to the gate of the third-first transistor T3-1c, and the fourth-second transistor T4-2c may include a gate which receives the writing signal GW[n], a first terminal connected to the second terminal of the third-second transistor T3-2c, and a second terminal connected to the gate of the third-second transistor T3-2c.

The fifth-first transistor T5-1c may apply an initialization voltage VINIT to the first capacitor CST1c and the gate of the third-first transistor T3-1c in response to a fourth signal, or an initialization signal GI[n], and the fifth-second transistor T5-2c may apply the initialization voltage VINIT to the second capacitor CST2c and the gate of the third-second transistor T3-2c in response to the fourth signal, or the initialization signal GI[n]. In some embodiments, the fifth-first transistor T5-1c may include a gate which receives the initialization signal GI[n], a first terminal connected to the gate of the third-first transistor T3-1c, and a second terminal which receives the initialization voltage VINIT, and the fifth-second transistor T5-2c may include a gate which receives the initialization signal GI[n], a first terminal connected to the gate of the third-second transistor T3-2c, and a second terminal which receives the initialization voltage VINIT.

The sixth-first and seventh-first transistors T6-1c and T7-1c may be turned on in response to a fifth signal, or an emission signal EM[n], and the sixth-second and seventh-second transistors T6-2c and T7-2c may be turned on in response to the fifth signal, or the emission signal EM[n]. In some embodiments, the sixth-first transistor T6-1c may include a gate which receives the emission signal EM[n], a first terminal which receives the first power supply voltage ELVDD, and a second terminal connected to the first terminal of the third-first transistor T3-1c, and the seventh-first transistor T7-1c may include a gate which receives the emission signal EM[n], a first terminal connected to the second terminal of the third-first transistor T3-1c, and a second terminal connected to the first light emitting element EL1c. Further, the sixth-second transistor T6-2c may include a gate which receives the emission signal EM[n], a first terminal which receives the first power supply voltage ELVDD, and a second terminal connected to the first terminal of the third-second transistor T3-2c, and the seventh-second transistor T7-2c may include a gate which receives the emission signal EM[n], a first terminal connected to the second terminal of the third-second transistor T3-2c, and a second terminal connected to the second light emitting element EL2c.

The eighth-first transistor T8-1c may apply the initialization voltage VINIT to the first light emitting element EL1c in response to a sixth signal, or the bypass signal GB[n], and the eighth-second transistor T8-2c may apply the initialization voltage VINIT to the second light emitting element EL2c in response to the sixth signal, or the bypass signal GB[n]. In some embodiments, the eighth-first transistor T8-1c may include a gate which receives the bypass signal GB[n], a first terminal connected to an anode of the first light emitting element EL1c, and a second terminal which receives the initialization voltage VINIT, and the eighth-second transistor T8-2c may include a gate which receives the bypass signal GB[n], a first terminal connected to an anode of the second light emitting element EL2c, and a second terminal which receives the initialization voltage VINIT.

The first light emitting element EL1c may emit light based on the first driving current generated by the third-first transistor T3-1c, and the second light emitting element EL2c may emit light based on the second driving current generated by the third-second transistor T3-2c. According to embodiments, each of the first and second light emitting elements EL1c and EL2c can be an OLED, an NED, a QD light emitting diode, a micro light emitting diode, an inorganic light emitting diode, or any other suitable light emitting element. In some embodiments, the first light emitting element EL1c may include the anode connected to the second terminal of the seventh-first transistor T7-1c and the first terminal of the eighth-first transistor T8-1c, and a cathode which receives a second power supply voltage ELVSS, and the second light emitting element EL2c may include the anode connected to the second terminal of the seventh-second transistor T7-2c and the first terminal of the eighth-second transistor T8-2c, and a cathode which receives the second power supply voltage ELVSS.

In some embodiments, the first-first transistor T1-1c and the first-second transistor T1-2c may have different types from each other, and each of the second-first, third-first, fourth-first, fifth-first, sixth-first, seventh-first, eighth-first, second-second, third-second, fourth-second, fifth-second, sixth-second, seventh-second and eighth-second transistors T2-1c, T3-1c, T4-1c, T5-1c, T6-1c, T7-1c, T8-1c, T2-2c, T3-2c, T4-2c, T5-2c, T6-2c, T7-2c and T8-2c may have any type. For example, as illustrated in FIG. 7, the first-first, second-first, third-first, fourth-first, fifth-first, sixth-first, seventh-first, eighth-first, second-second, third-second, fourth-second, fifth-second, sixth-second, seventh-second and eighth-second transistors T1-1c, T2-1c, T3-1c, T4-1c, T5-1c, T6-1c, T7-1c, T8-1c, T2-2c, T3-2c, T4-2c, T5-2c, T6-2c, T7-2c and T8-2c may be P-type transistors (e.g., PMOS transistors), and the first-second transistor T1-2c may be an N-type transistor (e.g., NMOS transistor), but is not limited thereto.

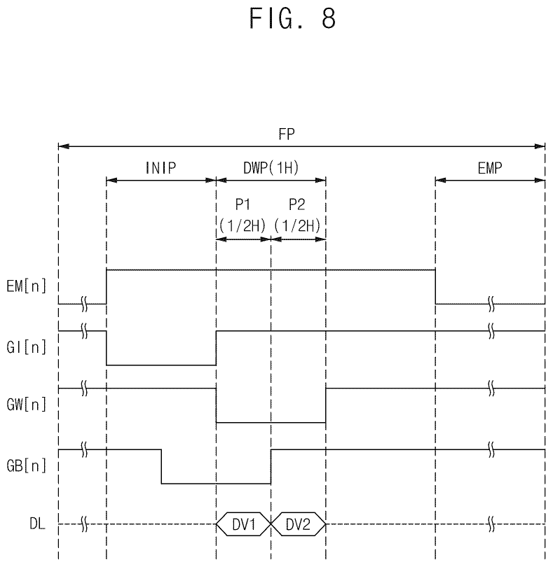

FIG. 8 is a timing diagram for describing an example of an operation of a first pixel and a second pixel illustrated in FIG. 7.

Referring to FIGS. 7 and 8, a frame period FP may include an initialization period INIP in which the first and second capacitors CST1c and CST2c are initialized, a data writing period DWP in which the first and second data voltages DV1 and DV2 are written to the first and second pixels PX1c and PX2c, and an emission period EMP in which the first and second light emitting elements EL1c and EL2c emit light.

In the initialization period INIP, the initialization signal GI[n] may have a low level, and the emission signal EM[n] and the writing signal GW[n] may have a high level. Thus, in the initialization period INIP, the fifth-first and fifth-second transistors T5-1c and T5-2c may be turned on, and the initialization voltage VINIT may be applied to the first and second capacitors CST1c and CST2c. The first and second capacitors CST1c and CST2c may be initialized based on the initialization voltage VINIT.

Further, the bypass signal GB[n] may have the low level during a portion of the initialization period INIP and a first period P1 of the data writing period DWP. Thus, in the portion of the initialization period INIP and the first period P1 of the data writing period DWP, the eighth-first and eighth-second transistors T8-1c and T8-2c may be turned on, and the initialization voltage VINIT may be applied to the first and second light emitting elements EL1c and EL2c. The first and second light emitting elements EL1c and EL2c may be initialized based on the initialization voltage VINIT.

In the first period P1 of the data writing period DWP, the bypass signal GB[n] and the writing signal GW[n] may have the low level, the emission signal EM[n] and the initialization signal GI[n] may have the high level, and the first data voltage DV1 for the first pixel PX1c may be applied to the data line DL. Thus, in the first period P1 of the data writing period DWP, the first-first transistor T1-1c, the second-first transistor T2-1c and the fourth-first transistor T4-1c may be turned on, the fourth-first transistor T4-1c may diode-connect the third-first transistor T3-1c, and the first capacitor CST1c may store the first data voltage DV1 transferred from the data line DL through the first-first transistor T1-1c, the second-first transistor T2-1c and the diode-connected third-first transistor T3-1c. Accordingly, the first capacitor CST1c may store the first data voltage DV1 in which a he threshold voltage of the third-first transistor T3-1c is compensated. Further, in the first period P1 of the data writing period DWP, although the second-second transistor T2-2c and the fourth-second transistor T4-2c are turned on, the first-second transistor T1-2c may be turned off, and thus the second capacitor CST2c may be electrically disconnected from the data line DL.

In a second period P2 of the data writing period DWP, the writing signal GW[n] may have the low level, the emission signal EM[n], the initialization signal GI[n] and the bypass signal GB[n] may have the high level, and the second data voltage DV2 for the second pixel PX2c may be applied to the data line DL. Thus, in the second period P2 of the data writing period DWP, the first-second transistor T1-2c, the second-second transistor T2-2c and the fourth-second transistor T4-2c may be turned on, the fourth-second transistor T4-2c may diode-connect the third-second transistor T3-2c, and the second capacitor CST2c may store the second data voltage DV2 transferred from the data line DL through the first-second transistor T1-2c, the second-second transistor T2-2c and the diode-connected third-second transistor T3-2c. Accordingly, the second capacitor CST2c may store the second data voltage DV2 in which a threshold voltage of the third-second transistor T3-2c is compensated. Further, in the second period P2 of the data writing period DWP, although the second-first transistor T2-1c and the fourth-first transistor T4-1c may be turned on, the first-first transistor T1-1c may be turned off, and thus that the first capacitor CST1c may be electrically disconnected from the data line DL. Accordingly, the display panel 100c may perform a demultiplexing operation without a separate demultiplexer circuit.

In some embodiments, the bypass signal GB[n] may be shifted by about ½ horizontal time ½H from the writing signal GW[n]. For example, as illustrated in FIG. 8, the bypass signal GB[n] may lead the writing signal GW[n] by about ½ horizontal time ½H.

In the emission period EMP, the emission signal EM[n] may have the low level, and the initialization signal GI[n], the writing signal GW[n] and the bypass signal GB[n] may have the high level. Thus, in the emission period EMP, the sixth-first, seventh-first, sixth-second and seventh-second transistors T6-1c, T7-1c, T6-2c and T7-2c may be turned on in response to the emission signal EM[n], the third-first transistor T3-1c may generate the first driving current based on the first data voltage DV1 stored in the first capacitor CST1c, the third-second transistor T3-2c may generate the second driving current based on the second data voltage DV2 stored in the second capacitor CST2c, the first light emitting element EL1c may emit light based on the first driving current, and the second light emitting element EL2c may emit light based on the second driving current.

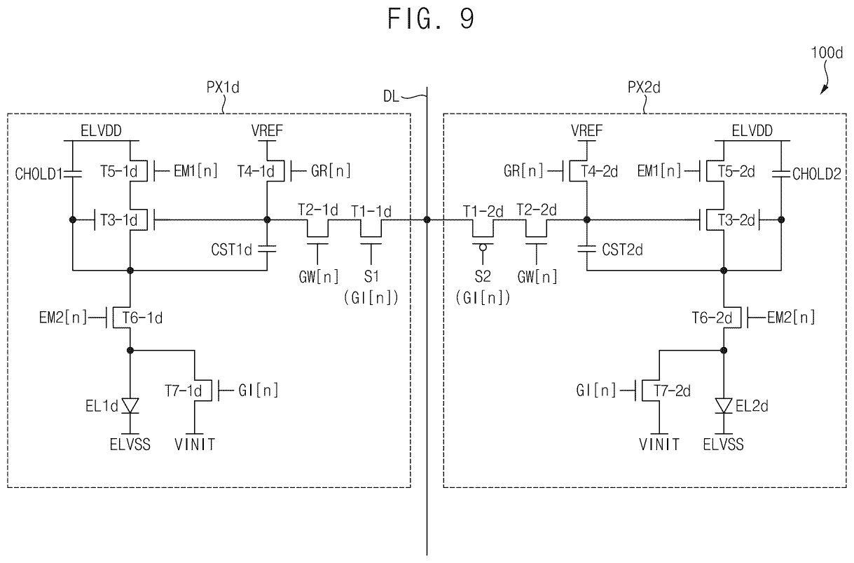

FIG. 9 is a circuit diagram illustrating a first pixel and a second pixel included in a display panel according to embodiments.

Referring to FIG. 9, a display panel 100d according to embodiments may include a data line DL, a first pixel PX1d and a second pixel PX2d. The first pixel PX1d may include a first-first transistor T1-1d, a second-first transistor T2-1d, a third-first transistor T3-1d, a first capacitor CST1d, a third capacitor CHOLD1, a fourth-first transistor T4-1d, a fifth-first transistor T5-1d, a sixth-first transistor T6-1d, a seventh-first transistor T7-1d and a first light emitting element EL1d, and the second pixel PX2d may include a first-second transistor T1-2d, a second-second transistor T2-2d, a third-second transistor T3-2d, a second capacitor CST2d, a fourth capacitor CHOLD2, a fourth-second transistor T4-2d, a fifth-second transistor T5-2d, a sixth-second transistor T6-2d, a seventh-second transistor T7-2d and a second light emitting element.

The first-first transistor T1-1d and the first-second transistor T1-2d may receive a first signal S1 and a second signal S2, respectively. In some embodiments, the first-first transistor T1-1d and the first-second transistor T1-2d may have different types from each other, and the first signal S1 and the second signal S2 may be the same initialization signal GI[n]. Further, the first-first transistor T1-1d may be located in a first path from the data line DL to the first capacitor CST1d, and the first-second transistor T1-2d may be located in a second path from the data line DL to the second capacitor CST2d. For example, the first-first transistor T1-1d may be connected in series with the second-first transistor T2-1d between the data line DL and a gate of the third-first transistor T3-1d, and the first-second transistor T1-2d may be connected in series with the second-second transistor T2-2d between the data line DL and a gate of the third-second transistor T3-2d. In some embodiments, the first-first transistor T1-1d may include a gate which receives the initialization signal GI[n], a first terminal connected to the data line DL, and a second terminal connected to the second-first transistor T2-1d, and the first-second transistor T1-2d may include a gate which receives the initialization signal GI[n], a first terminal connected to the data line DL, and a second terminal connected to the second-second transistor T2-2d.

The second-first transistor T2-1d may be turned on in response to a third signal, or a writing signal GW[n], and the second-second transistor T2-2d may be turned on in response to the third signal, or the writing signal GW[n]. In some embodiments, the second-first transistor T2-1d may include a gate which receives the writing signal GW[n], a first terminal connected to the second terminal of the first-first transistor T1-1d, and a second terminal connected to the first capacitor CST1d, the third-first transistor T3-1d and the fourth-first transistor T4-1d, and the second-second transistor T2-2d may include a gate which receives the writing signal GW[n], a first terminal connected to the second terminal of the first-second transistor T1-2d, and a second terminal connected to the second capacitor CST2d, the third-second transistor T3-2d and the fourth-second transistor T4-2d.

The third-first transistor T3-1d may generate a first driving current based on a first data voltage stored in the first capacitor CST1d, and the third-second transistor T3-2d may generate a second driving current based on a second data voltage stored in the second capacitor CST2d. In some embodiments, the third-first transistor T3-1d may include a first gate (e.g., a top gate) connected to a first electrode of the first capacitor CST1d and the second terminal of the second-first transistor T2-1d, a first terminal connected to the fifth-first transistor T5-1d, a second terminal connected to the sixth-first transistor T6-1d, and a second gate (e.g., a bottom gate) connected to the third capacitor CHOLD1, and the third-second transistor T3-2d may include a first gate (e.g., a top gate) connected to a first electrode of the second capacitor CST2d and the second terminal of the second-second transistor T2-2d, a first terminal connected to the fifth-second transistor T5-2d, a second terminal connected to the sixth-second transistor T6-2d, and a second gate (e.g., a bottom gate) connected to the fourth capacitor CHOLD2.

The first capacitor CST1d may store the first data voltage transferred from the data line DL through the first-first transistor T1-1d and the second-first transistor T2-1d, and the second capacitor CST2d may store the second data voltage transferred from the data line DL through the first-second transistor T1-2d and the second-second transistor T2-2d. In some embodiments, the first capacitor CST1d may include a first electrode connected to the first gate of the third-first transistor T3-1d, and a second electrode connected to the second terminal and the second gate of the third-first transistor T3-1d, and the second capacitor CST2d may include a first electrode connected to the first gate of the third-second transistor T3-2d, and a second electrode connected to the second terminal and the second gate of the third-second transistor T3-2d.

The third capacitor CHOLD1 may hold a voltage of the second gate of the third-first transistor T3-1d, and the fourth capacitor CHOLD2 may hold a voltage of the second gate of the third-second transistor T3-2d. In some embodiments, the third capacitor CHOLD1 may include a first electrode which receives a first power supply voltage ELVDD, and a second electrode connected to the second terminal and the second gate of the third-first transistor T3-1d, and the fourth capacitor CHOLD2 may include a first electrode which receives the first power supply voltage ELVDD, and a second electrode connected to the second terminal and the second gate of the third-second transistor T3-2d.

The fourth-first transistor T4-1d may apply a reference voltage VREF to the first electrode of the first capacitor CST1d in response to a fourth signal, or a reference signal GR[n], and the fourth-second transistor T4-2d may apply the reference voltage VREF to the first electrode of the second capacitor CST2d in response to the fourth signal, or the reference signal GR[n]. In some embodiments, the fourth-first transistor T4-1d may include a gate which receives the reference signal GR[n], a first terminal which receives the reference voltage VREF, and a second terminal connected to the first electrode of the first capacitor CST1d and the first gate of the third-first transistor T3-1d, and the fourth-second transistor T4-2d may include a gate which receives the reference signal GR[n], a first terminal which receives the reference voltage VREF, and a second terminal connected to the first electrode of the second capacitor CST2d and the first gate of the third-second transistor T3-2d.

The fifth-first transistor T5-1d may be turned on in response to a fifth signal, or a first emission signal EM1[n], the sixth-first transistor T6-1d may be turned on in response to a sixth signal, or a second emission signal EM2[n], the fifth-second transistor T5-2d may be turned on in response to the fifth signal, or the first emission signal EM1[n], and the sixth-second transistor T6-2d may be turned on in response to the sixth signal, or the second emission signal EM2[n]. In some embodiments, the fifth-first transistor T5-1d may include a gate which receives the first emission signal EM1[n], a first terminal which receives the first power supply voltage ELVDD, and a second terminal connected to the first terminal of the third-first transistor T3-1d, and the seventh-first transistor T7-1d may include a gate which receives the second emission signal EM2[n], a first terminal connected to the second terminal of the third-first transistor T3-1d, and a second terminal connected to the first light emitting element EL1d. Further, the fifth-second transistor T5-2d may include a gate which receives the first emission signal EM1[n], a first terminal which receives the first power supply voltage ELVDD, and a second terminal connected to the first terminal of the third-second transistor T3-2d, and the seventh-second transistor T7-2d may include a gate which receives the second emission signal EM2[n], a first terminal connected to the second terminal of the third-second transistor T3-2d, and a second terminal connected to the second light emitting element EL2d.

The seventh-first transistor T7-1d may apply an initialization voltage VINIT to the first light emitting element EL1d in response to a seventh signal, or an initialization signal GI[n], and the seventh-second transistor T7-2d may apply the initialization voltage VINIT to the second light emitting element EL2d in response to the seventh signal, or the initialization signal GI[n]. In some embodiments, the initialization voltage VINIT may be substantially equal to the reference voltage VREF, but is not limited thereto. In some embodiments, the seventh-first transistor T7-1d may include a gate which receives the initialization signal GI[n], a first terminal connected to an anode of the first light emitting element EL1d, and a second terminal which receives the initialization voltage VINIT, and the seventh-second transistor T7-2d may include a gate which receives the initialization signal GI[n], a first terminal connected to an anode of the second light emitting element EL2d, and a second terminal which receives the initialization voltage VINIT.

The first light emitting element EL1d may emit light based on the first driving current generated by the third-first transistor T3-1d, and the second light emitting element EL2d may emit light based on the second driving current generated by the third-second transistor T3-2d. According to embodiments, each of the first and second light emitting elements EL1d and EL2d may be an OLED, a NED, a QD light emitting diode, a micro light emitting diode, an inorganic light emitting diode, or any other suitable light emitting element. In some embodiments, the first light emitting element EL1d may include the anode connected to the second terminal of the sixth-first transistor T6-1d and the first terminal of the seventh-first transistor T7-1d, and a cathode which receives a second power supply voltage ELVSS, and the second light emitting element EL2d may include the anode connected to the second terminal of the sixth-second transistor T6-2d and the first terminal of the seventh-second transistor T7-2d, and a cathode which receives the second power supply voltage ELVSS.

In some embodiments, the first-first transistor T1-1d and the first-second transistor T1-2d may have different types from each other, and each of the second-first, third-first, fourth-first, fifth-first, sixth-first, seventh-first, second-second, third-second, fourth-second, fifth-second, sixth-second, and seventh-second transistors T2-1d, T3-1d, T4-1d, T5-1d, T6-1d, T7-1d, T2-2d, T3-2d, T4-2d, T5-2d, T6-2d and T7-2d may have any type. For example, as illustrated in FIG. 9, the first-first, second-first, third-first, fourth-first, fifth-first, sixth-first, seventh-first, second-second, third-second, fourth-second, fifth-second, sixth-second, and seventh-second transistors T1-1d, T2-1d, T3-1d, T4-1d, T5-1d, T6-1d, T7-1d, T2-2d, T3-2d, T4-2d, T5-2d, T6-2d and T7-2d may be N-type transistors (e.g., NMOS transistors), and the first-second transistor T1-2d may be a P-type transistor (e.g., PMOS transistor), but is not limited thereto.

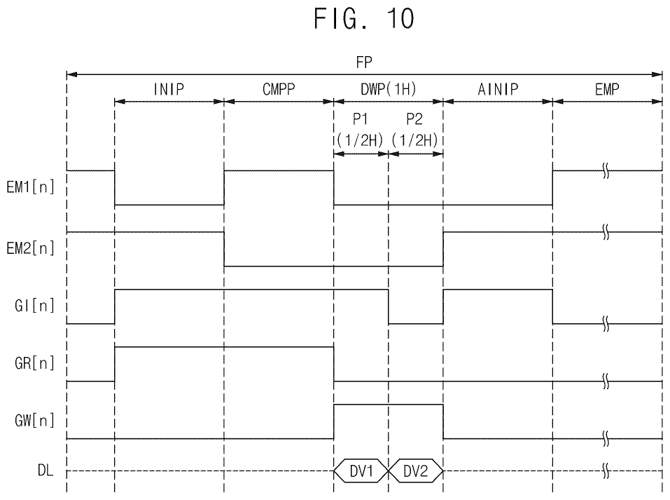

FIG. 10 is a timing diagram for describing an example of an operation of a first pixel and a second pixel illustrated in FIG. 9.

Referring to FIGS. 9 and 10, a frame period FP may include an initialization period INIP in which the first, second, third and fourth capacitors CST1d, CST2d, CHOLD1 and CHOLD2 are initialized, a compensation period CMPP in which threshold voltages of the third-first and third-second transistors T3-1d and T3-2d are compensated, a data writing period DWP in which the first and second data voltages DV1 and DV2 are written to the first and second pixels PX1d and PX2d, an anode initialization period AINIP in which the first and second light emitting elements EL1d and EL2d are initialized, and an emission period EMP in which the first and second light emitting elements EL1d and EL2d emit light.

In the initialization period INIP, the second emission signal EM2[n], the initialization signal GI[n] and the reference signal GR[n] may have a high level, and the first emission signal EM1[n] and the writing signal GW[n] may have a low level. Thus, in the initialization period INIP, the fourth-first, sixth-first, seventh-first, fourth-second, sixth-second and seventh-second transistors T4-1d, T6-1d, T7-1d, T4-2d, T6-2d and T7-2d may be turned on, the fourth-first and fourth-second transistors T4-1d and T4-2d may apply the reference voltage VREF to the first electrodes of the first and second capacitors CST1d and CST2d, the sixth-first and seventh-first transistors T6-1d and T7-1d may apply the initialization voltage VINIT to the second electrode of the first capacitor CST1d and the second electrode of the third capacitor CHOLD1, and the sixth-second and seventh-second transistors T6-2d and T7-2d may apply the initialization voltage VINIT to the second electrode of the second capacitor CST2d and the second electrode of the second electrode and the fourth capacitor CHOLD2. Accordingly, the first and second capacitors CST1d and CST2d may be initialized based on the reference voltage VREF and the initialization voltage VINIT, and the third and fourth capacitors CHOLD1 and CHOLD2 may be initialized based on the first power supply voltage ELVDD and the initialization voltage VINIT. Further, the seventh-first and seventh-second transistors T7-1d and T7-2d may apply the initialization voltage VINIT to the first and second light emitting elements EL1d and EL2d, and the first and second light emitting elements EL1d and EL2d may be initialized based on the initialization voltage VINIT.

In the compensation period CMPP, the first emission signal EM1[n], the initialization signal GI[n] and the reference signal GR[n] may have the high level, and the second emission signal EM2[n] and the writing signal GW[n] may have the low level. Thus, in the compensation period CMPP, the fourth-first, fifth-first, fourth-second, and fifth-second transistors T4-1d, T5-1d, T4-2d and T5-2d may be turned on, the fourth-first and fourth-second transistors T4-1d and T4-2d may apply the reference voltage VREF to the first gates of the third-first and third-second transistors T3-1d and T3-2d, and the fifth-first and fifth-second transistors T5-1d and T5-2d may apply the first power supply voltage ELVDD to the first terminals of the third-first and third-second transistors T3-1d and T3-2d. Accordingly, the third-first transistor T3-1d may be turned on until the threshold voltage of the third-first transistor T3-1d is stored in the first capacitor CST1d, and the third-second transistor T3-2d may be turned on until the threshold voltage of the third-second transistor T3-2d is stored in the second capacitor CST2d. Further, the seventh-first and seventh-second transistors T7-1d and T7-2d may apply the initialization voltage VINIT to the first and second light emitting elements EL1d and EL2d, and the first and second light emitting elements EL1d and EL2d may be initialized based on the initialization voltage VINIT.

In a first period P1 of the data writing period DWP, the initialization signal GI[n] and the writing signal GW[n] may have the high level, the first emission signal EM1[n], the second emission signal EM2[n] and the reference signal GR[n] may have the low level, and the first data voltage DV1 for the first pixel PX1d may be applied to the data line DL. Thus, in the first period P1 of the data writing period DWP, the first-first transistor T1-1d and the second-first transistor T2-1d may be turned on, and the first capacitor CST1d may store the first data voltage DV1 transferred from the data line DL through the first-first transistor T1-1d and the second-first transistor T2-1d at the first electrode of the first capacitor CST1d. Further, the seventh-first and seventh-second transistors T7-1d and T7-2d may apply the initialization voltage VINIT to the first and second light emitting elements EL1d and EL2d, and the first and second light emitting elements EL1d and EL2d may be initialized based on the initialization voltage VINIT. Further, in the first period P1 of the data writing period DWP, although the second-second transistor T2-2d is turned on, the first-second transistor T1-2d may be turned off, and thus the second capacitor CST2d may be electrically disconnected from the data line DL.

In a second period P2 of the data writing period DWP, the writing signal GW[n] may have the high level, the first emission signal EM1[n], the second emission signal EM2[n], the initialization signal GI[n] and the reference signal GR[n] may have the low level, and the second data voltage DV2 for the second pixel PX2d may be applied to the data line DL. Thus, in the second period P2 of the data writing period DWP, the first-second transistor T1-2d and the second-second transistor T2-2d may be turned on, and the second capacitor CST2d may store the second data voltage DV2 transferred from the data line DL through the first-second transistor T1-2d and the second-second transistor T2-2d at the first electrode of the second capacitor CST2d. Further, in the second period P2 of the data writing period DWP, although the second-first transistor T2-1d is turned on, the first-first transistor T1-1d may be turned off, and thus the first capacitor CST1d may be electrically disconnected from the data line DL. Accordingly, the display panel 100d may perform a demultiplexing operation without a separate demultiplexer circuit.

In the anode initialization period INIP, the initialization signal GI[n] may have the high level, and the first emission signal EM1[n], the reference signal GR[n] and the writing signal GW[n] may have the low level. In some embodiments, the second emission signal EM2[n] may have the high level as illustrated in FIG. 10, but is not limited thereto. In other embodiments, the second emission signal EM2[n] may have the low level in the anode initialization period INIP. Thus, in the initialization period INIP, the seventh-first and seventh-second transistors T7-1d and T7-2d may be turned on, the seventh-first and seventh-second transistors T7-1d and T7-2d may apply the initialization voltage VINIT to the first and second light emitting elements EL1d and EL2d, and the first and second light emitting elements EL1d and EL2d may be initialized based on the initialization voltage VINIT.

In the emission period EMP, the first emission signal EM1[n] and the second emission signal EM2[n] may have the high level, and the initialization signal GI[n], the reference signal GR[n] and the writing signal GW[n] may have the low level. Thus, in the emission period EMP, the fifth-first, sixth-first, fifth-second and sixth-second transistors T5-1d, T6-1d, T5-2d and T6-2d may turned on in response to the first and second emission signals EM1[n] and EM2[n], the third-first transistor T3-1d may generate the first driving current based on the first data voltage DV1 stored by the first capacitor CST1d, the third-second transistor T3-2d may generate the second driving current based on the second data voltage DV2 stored by the second capacitor CST2d, the first light emitting element EL1d may emit light based on the first driving current, and the second light emitting element EL2d may emit light based on the second driving current.

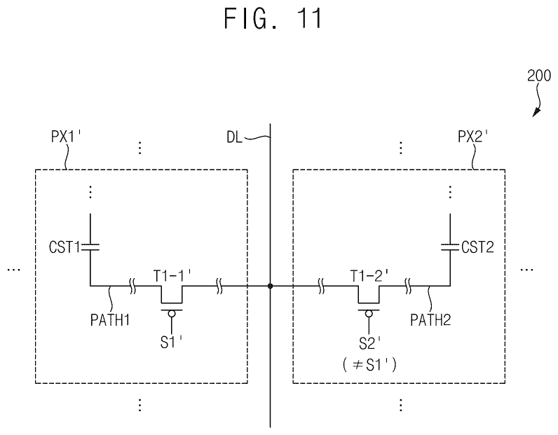

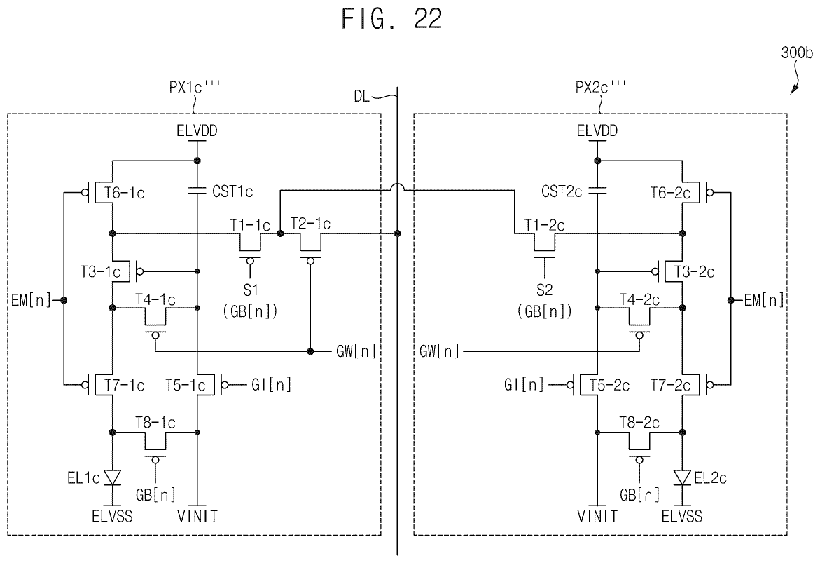

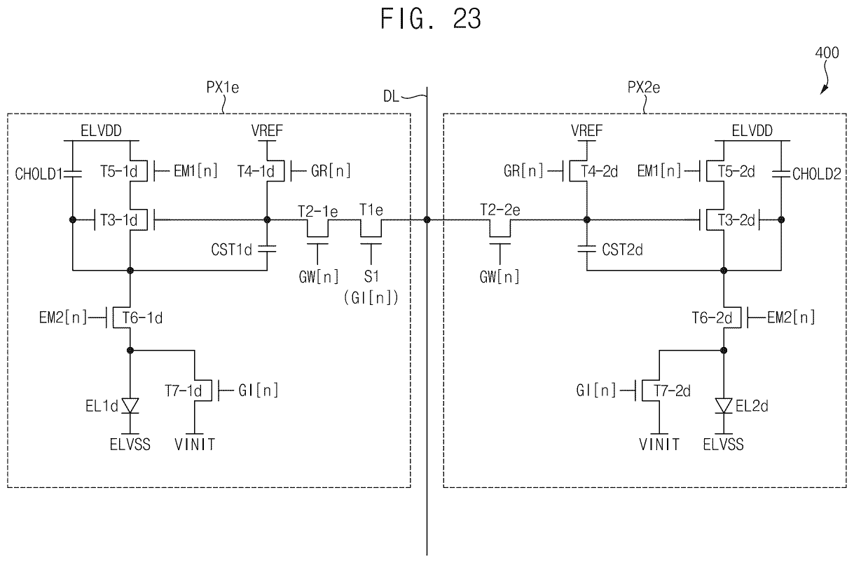

Although FIGS. 3 and 5 illustrate examples in which the first-first and first-second transistors T1-1a, T1-2a, T1-1b and T1-2b having different types are added to first and second pixels each having a 2T1C pixel structure, FIG. 7 illustrates an example in which the first-first and first-second transistors T1-1c and T1-2c having different types are added to first and second pixels each having a 7T1C pixel structure, and FIG. 9 illustrates an example in which the first-first and first-second transistors T1-1d and T1-2d having different types are added to first and second pixels each having a 6T2C pixel structure, in the display panel 100 according to embodiments, the first-first and first-second transistors T1-1 and T1-2 having different types may be added to first and second pixels each having an arbitrary pixel structure. Further, in other embodiments, as described below with reference to FIGS. 11 through 20, first-first and first-second transistors T1-1′ and T1-2′ having the same type may be added to first and second pixels each having an arbitrary pixel structure. In still other embodiments, as described below with reference to FIGS. 22 and 23, a first transistor T1e may be added to one of first and second pixels each having an arbitrary pixel structure.

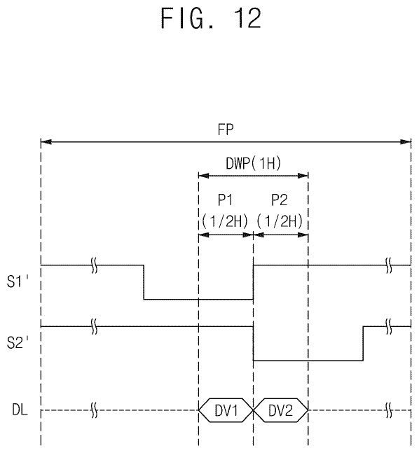

FIG. 11 is a diagram illustrating a portion of a first pixel and a portion of a second pixel included in a display panel according to embodiments, and FIG. 12 is a timing diagram for describing an example of an operation of a first pixel and a second pixel illustrated in FIG. 11.

Referring to FIG. 11, a display panel 200 according to embodiments may include a data line DL, a first pixel PX1′ connected to the data line DL, and a second pixel PX2′ connected to the data line DL.

The first pixel PX1′ may include a first capacitor CST1, and a first-first transistor T1-1′ located in a first path PATH1 from the data line DL to the first capacitor CST1, and the second pixel PX2 may include a second capacitor CST2, and a first-second transistor T1-2′ located in a second path PATH2 from the data line DL to the second capacitor CST2. The first-first transistor T1-1′ may be turned on in response to a first signal S1′ in a first period within a data writing period, and the first-second transistor T1-2′ may be turned on in response to a second signal S2′ different from the first signal S1′ in a second period within the data writing period.

In some embodiments, as illustrated in FIGS. 11 and 12, the first-first transistor T1-1′ and the first-second transistor T1-2′ may have the same type, the first signal S1′ may have a first level in the first period P1 of the data writing period DWP and may have a second level in the second period P2 of the data writing period DWP, and the second signal S2′ may have the second level in the first period P1 of the data writing period DWP and may have the first level in the second period P2 of the data writing period DWP. Further, in some embodiments, the second signal S2′ may be shifted by about 1 horizontal time 1H from the first signal S1′, but is not limited thereto. For example, the second signal S2′ may lag the first signal S1′ by about 1 horizontal time 1H.

For example, as illustrated in FIGS. 11 and 12, the first-first transistor T1-1′ and the first-second transistor T1-2′ may be P-type transistors (e.g., PMOS transistors). Further, in the first period P1 of the data writing period DWP, the first signal S1′ may have a low level, the second signal S2′ may have a high level, and a first data voltage DV1 for the first pixel PX1′ may be provided to the data line DL. Thus, in the first period P1 of the data writing period DWP, the first-first transistor T1-1′ may be turned on, the first-second transistor T1-2′ may be turned off, the first data voltage DV1 may be transferred from the data line DL to the first capacitor CST1 through the first-first transistor T1-1′, and the first capacitor CST1 may store the first data voltage DV1. Further, in the second period P2 of the data writing period DWP, the first signal S1′ may have the high level, the second signal S2′ may have the low level, and the second data voltage DV2 for the second pixel PX2′ may be provided to the data line DL. Thus, in the second period P2 of the data writing period DWP, the first-first transistor T1-1′ may be turned off, the first-second transistor T1-2′ may be turned on, the second data voltage DV2 may be transferred from the data line DL to the second capacitor CST2 through the first-second transistor T1-2′, and the second capacitor CST2 may store the second data voltage DV2.

Accordingly, the display panel 200 according to embodiments may perform a demultiplexing operation by using the first and second transistors T1-1′ and T1-2′ having the same type included in the first and second pixels PX1′ and PX2′ without a demultiplexer circuit. Thus, a size of a non-display region of the display panel 200 may be reduced, power consumption may be reduced, and the number of data lines may be reduced.

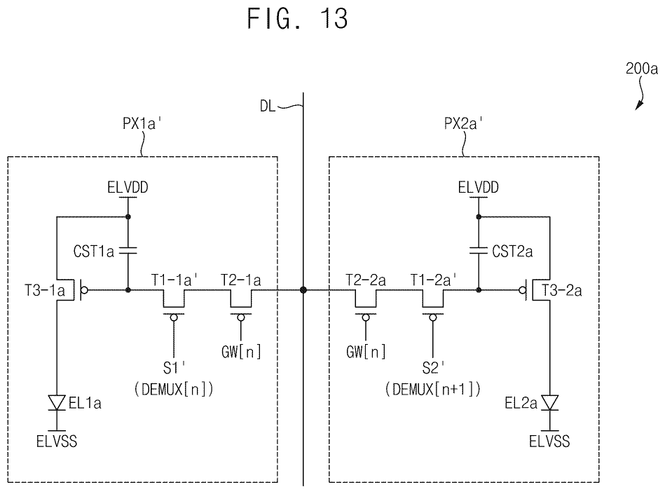

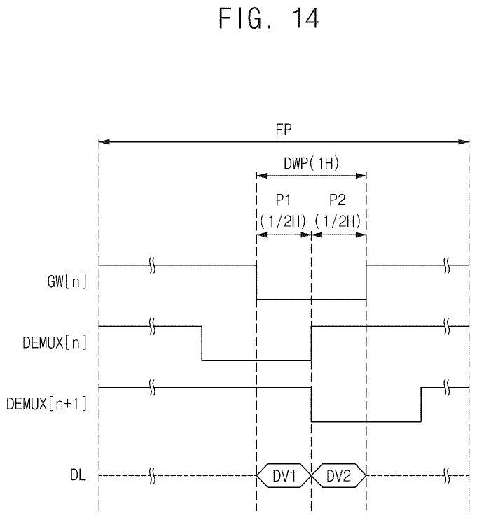

FIG. 13 is a circuit diagram illustrating a first pixel and a second pixel included in a display panel according to embodiments, and FIG. 14 is a timing diagram for describing an example of an operation of a first pixel and a second pixel illustrated in FIG. 13.

Referring to FIG. 13, a display panel 200a according to embodiments may include a data line DL, a first pixel PX1a′ and a second pixel PX2a′. The first pixel PX1a′ may include a first-first transistor T1-1a′, a second-first transistor T2-1a, a third-first transistor T3-1a, a first capacitor CST1a and a first light emitting element EL1a, and the second pixel PX2a′ may include a first-second transistor T1-2a′, a second-second transistor T2-2a, a third-second transistor T3-2a, a second capacitor CST2a and a second light emitting element EL2a. The display panel 200a of FIG. 13 may have substantially the same configuration and substantially the same operation as a display panel 100a of FIG. 3, except that the first-first transistor T1-1a′ and the first-second transistor T1-2a′ may have the same type, and a first signal S1′ and a second signal S2′ may be different signals.

In some embodiments, as illustrated in FIG. 13, the first-first transistor T1-1a′ and the first-second transistor T1-2a′ may be P-type transistors (e.g., PMOS transistors). Further, the second-first, third-first, second-second and third-second transistors T2-1a, T3-1a, T2-2a and T3-2a also may be P-type transistors.

The first-first transistor T1-1a′ may receive the first signal S1′, the first-second transistor T1-2a′ may receive the second signal S2′, and the second-first and second-second transistors T2-1a and T2-2a may receive a third signal, or a writing signal GW[n]. In some embodiments, the second signal S2′ applied to the first-second transistor T1-2a′ may be shifted by 1 horizontal time from the first signal S1′ applied to the first-first transistor T1-1a′. For example, in a case where the first pixel PX1a′ and the second pixel PX2a′ are arranged in an N-th pixel row, where N is an integer greater than or equal to 1, the first signal S1′ may be an N-th demultiplexing signal DEMUX[n] for the N-th pixel row, the second signal S2′ may be an (N+1)-th demultiplexing signal DEMUX[n+1] for an (N+1)-th pixel row, and the third signal may be the writing signal GW[n] for the N-th pixel row. Further, in some embodiments, the first signal S1′, or the N-th demultiplexing signal DEMUX[n] may lead the third signal, or the writing signal GW[n] by ½ horizontal time, and the second signal S2′, or the (N+1)-th demultiplexing signal DEMUX[n+1] may lag the third signal, or the writing signal GW[n] by ½ horizontal time.

For example, as illustrated in FIG. 14, the first signal S1′, or the N-th demultiplexing signal DEMUX[n] may have a first level (e.g., a low level) in a first period P1 of a data writing period DWP, and may have a second level (e.g., a high level) in a second period P2 of the data writing period DWP. The second signal S2′, or the (N+1)-th demultiplexing signal DEMUX[n+1] may have the second level in the first period P1 of the data writing period DWP, and may have the first level in the second period P2 of the data writing period DWP. The third signal, or the writing signal GW[n] may have an on-level or the first level during the data writing period DWP. Thus, in the first period P1 of the data writing period DWP, the first-first and second-first transistors T1-1a′ and T2-1a may be turned on, and a first data voltage DV1 for the first pixel PX1a′ may be stored in the first capacitor CST1a. Further, in the second period P2 of the data writing period DWP, the first-second and second-second transistors T1-2a′ and T2-2a may be turned on, and a second data voltage DV2 for the second pixel PX2a′ may be stored in the second capacitor CST2a. Accordingly, the display panel 200a may perform a demultiplexing operation without a separate demultiplexer circuit.

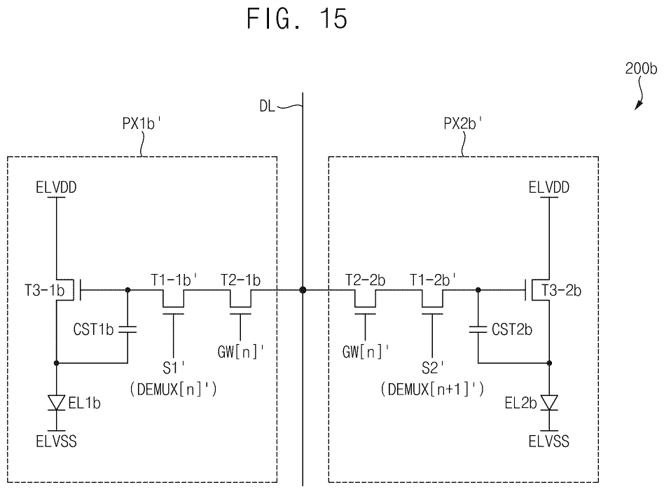

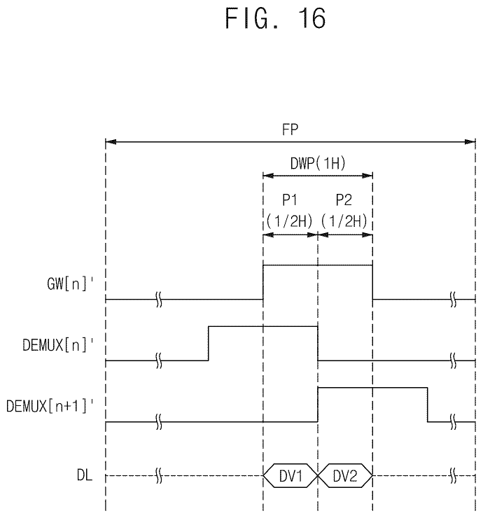

FIG. 15 is a circuit diagram illustrating a first pixel and a second pixel included in a display panel according to embodiments, and FIG. 16 is a timing diagram for describing an example of an operation of a first pixel and a second pixel illustrated in FIG. 15.

Referring to FIG. 15, a display panel 200b according to embodiments may include a data line DL, a first pixel PX1b′ and a second pixel PX2b′. The first pixel PX1b′ may include a first-first transistor T1-1b′, a second-first transistor T2-1b, a third-first transistor T3-1b, a first capacitor CST1b and a first light emitting element EL1b, and the second pixel PX2b may include a first-second transistor T1-2b′, a second-second transistor T2-2b, a third-second transistor T3-2b, a second capacitor CST2b and a second light emitting element EL2b. The display panel 200b of FIG. 15 may have substantially the same configuration and substantially the same operation as a display panel 100b of FIG. 5, except that the first-first transistor T1-1b′ and the first-second transistor T1-2b′ may have the same type, and a first signal S1′ and a second signal S2′ may be different signals.

In some embodiments, as illustrated in FIG. 15, the first-first transistor T1-1b′ and the first-second transistor T1-2b′ may be N-type transistors (e.g., NMOS transistors). Further, the second-first, third-first, second-second and third-second transistors T2-1b, T3-1b, T2-2b and T3-2b may also be N-type transistors.

The first-first transistor T1-1b′ may receive the first signal S1′, the first-second transistor T1-2b′ may receive the second signal S2′, and the second-first and second-second transistors T2-1b and T2-2b may receive a third signal, or a writing signal GW[n]′. For example, in a case where the first pixel PX1b′ and the second pixel PX2b′ are arranged in an N-th pixel row, the first signal S1′ may be an N-th demultiplexing signal DEMUX[n]′ for the N-th pixel row, and the second signal S2′ may be an (N+1)-th demultiplexing signal DEMUX[n+1]′ for an (N+1)-th pixel row, and the third signal may be the writing signal GW[n]′ for the N-th pixel row.

For example, as illustrated in FIG. 16, the first signal S1′, or the N-th demultiplexing signal DEMUX[n]′ may have a second level (e.g., a high level) in a first period P1 of a data writing period DWP, and may have a first level (e.g., a low level) in a second period P2 of the data writing period DWP. The second signal S2′, or the (N+1)-th demultiplexing signal DEMUX[n+1]′ may have the first level in the first period P1 of the data writing period DWP, and may have the second level in the second period P2 of the data writing period DWP. The third signal, or the writing signal GW[n] may have an on-level or the second level during the data writing period DWP. Thus, in the first period P1 of the data writing period DWP, the first-first and second-first transistors T1-1b′ and T2-1b may be turned on, and a first data voltage DV1 for the first pixel PX1b′ may be stored in the first capacitor CST1b. Further, in the second period P2 of the data writing period DWP, the first-second and second-second transistors T1-2b′ and T2-2b may be turned on, and a second data voltage DV2 for the second pixel PX2b′ may be stored in the second capacitor CST2b. Accordingly, the display panel 200b may perform a demultiplexing operation without a separate demultiplexer circuit.

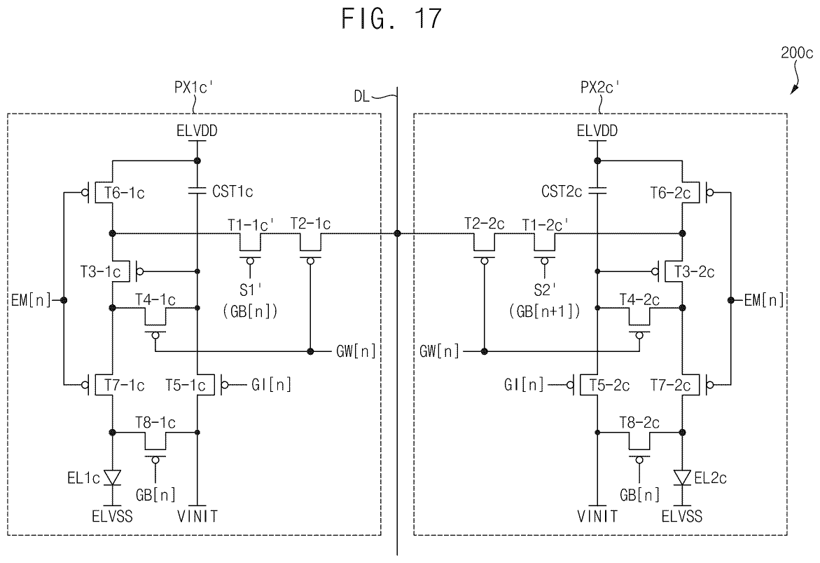

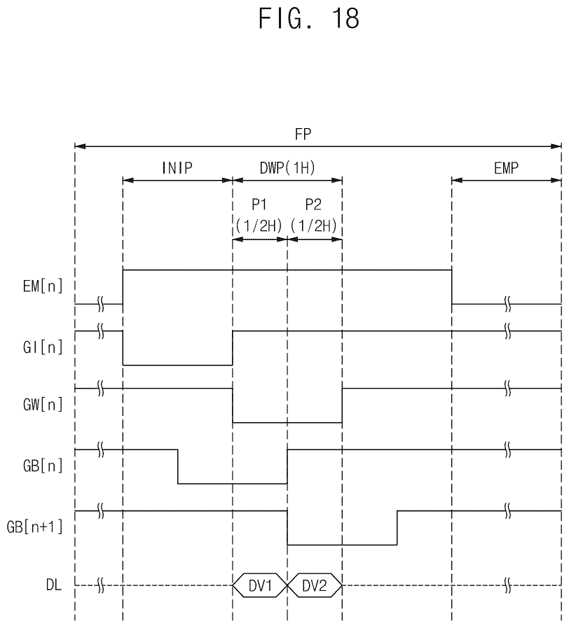

FIG. 17 is a circuit diagram illustrating a first pixel and a second pixel included in a display panel according to embodiments, and FIG. 18 is a timing diagram for describing an example of an operation of a first pixel and a second pixel illustrated in FIG. 17.

Referring to FIG. 17, a display panel 200c according to embodiments may include a data line DL, a first pixel PX1c′ and a second pixel PX2c′. The first pixel PX1c′ may include a first-first transistor T1-1c′, a second-first transistor T2-1c, a third-first transistor T3-1c, a first capacitor CST1c, a fourth-first transistor T4-1c, a fifth-first transistor T5-1c, a sixth-first transistor T6-1c, a seventh-first transistor T7-1c, an eighth-first transistor T8-1c and a first light emitting element EL1c, and the second pixel PX2c′ may include a first-second transistor T1-2c′, a second-second transistor T2-2c, a third-second transistor T3-2c, a second capacitor CST2c, a fourth-second transistor T4-2c, a fifth-second transistor T5-2c, a sixth-second transistor T6-2c, a seventh-second transistor T7-2c, an eighth-second transistor T8-2c and a second light emitting element EL2c. The display panel 200c of FIG. 17 may have substantially the same configuration and substantially the same operation as a display panel 100c of FIG. 7, except that the first-first transistor T1-1c′ and the first-second transistor T1-2c′ may have the same type, and a first signal S1′ and a second signal S2′ may be different signals.

In some embodiments, as illustrated in FIG. 17, the first-first transistor T1-1c′ and the first-second transistor T1-2c′ may be P-type transistors (e.g., PMOS transistors). Further, the second-first, third-first, fourth-first, fifth-first, sixth-first, seventh-first, eighth-first, second-second, third-second, fourth-second, fifth-second, sixth-second, seventh-second and eighth-second transistors T2-1c, T3-1c, T4-1c, T5-1c, T6-1c, T7-1c, T8-1c, T2-2c, T3-2c, T4-2c, T5-2c, T6-2c, T7-2c and T8-2c also may be P-type transistors.

The first-first transistor T1-1c′ may receive the first signal S1′, the first-second transistor T1-2c′ may receive the second signal S2′, the first signal S′ may be a bypass signal GB[n] for a pixel row in which the first and second pixels PX1c′ and PX2c′ are arranged, and the second signal S2′ may be a bypass signal GB[n+1] for another pixel row different from the pixel row. For example, as illustrated in FIGS. 17 and 18, in a case where the first and second pixels PX1c′ and PX2c′ are arranged in an N-th pixel row, the first signal S1′ may be an N-th bypass signal GB[n] for the Nth pixel row, and the second signal S2′ may be an (N+1)-th bypass signal GB[n+1] for an (N+1)-th pixel row. Further, the first signal S1′, or the N-th bypass signal GB[n] may lead a writing signal GW[n] by about ½ horizontal time, and the second signal S2′, or the (N+1)-th bypass signal GB[n+1] may lag the writing signal GW[n] by about ½ horizontal time.

Thus, as illustrated in FIG. 18, the N-th bypass signal GB[n] may have a first level (e.g., a low level) in a first period P1 of a data writing period DWP, and may have a second level (e.g., a high level) in a second period P2 of the data writing period DWP. The (N+1)-th bypass signal GB[n+1] may have the second level in the first period P1 of the data writing period DWP, and may have the first level in the second period P2 of the data writing period DWP. The writing signal GW[n] may have an on-level or the first level during the data writing period DWP. Thus, in the first period P1 of the data writing period DWP, the first-first transistor T1-1c′, the second-first transistor T2-1c and the fourth-first transistor T4-1c may be turned on, the fourth-first transistor T4-1c may diode-connect the third-first transistor T3-1c, and the first capacitor CST1c may store a first data voltage DV1 transferred from the data line DL through the first-first transistor T1-1c′, the second-first transistor T2-1c and the diode-connected third-first transistor T3-1c. Further, in the second period P2 of the data writing period DWP, the first-second transistor T1-2c′, the second-second transistor T2-2c and the fourth-second transistor T4-2c may be turned on, the fourth-second transistor T4-2c may diode-connect the third-second transistor T3-2c, and the second capacitor CST2c may store a second data voltage DV2 transferred from the data line DL through the first-second transistor T1-2c′, the second-second transistor T2-2c and the diode-connected third-second transistor T3-2c. Accordingly, the display panel 200c may perform a demultiplexing operation without a separate demultiplexer circuit.

Although FIGS. 17 and 18 illustrate an example in which the first signal S1′ is the N-th bypass signal GB[n] and the second signal S2′ is the (N+1)-th bypass signal GB[n+1], the first signal S1′ and the second signal S2′ according to embodiments are not limited to the example illustrated in FIGS. 17 and 18. In other embodiments, the first signal S1′ may be the (N+1)-th bypass signal GB[n+1], and the second signal S2′ may be the N-th bypass signal GB[n]. In still other embodiments, the N-th bypass signal GB[n] may lag the writing signal GW[n] by about ½ horizontal time unlike as illustrated in FIG. 18, the first signal S1′ may be an (N−1)-th bypass signal, and the second signal S2′ may be the N-th bypass signal GB[n]. In still other embodiments, the first signal S1′ may be the N-th bypass signal GB[n], and the second signal S2′ may be the (N−1)-th bypass signal.

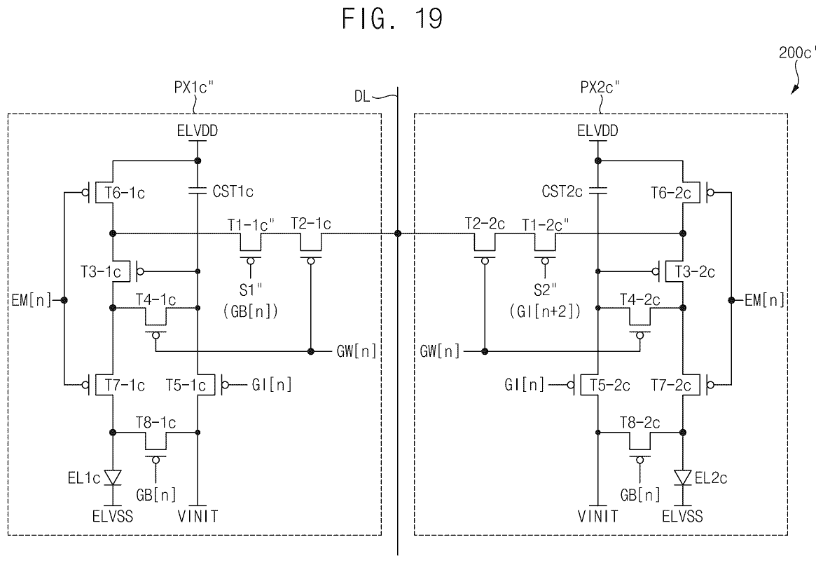

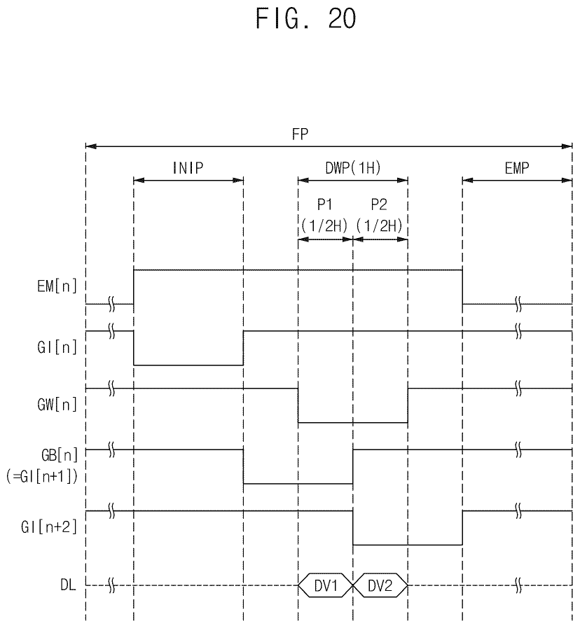

FIG. 19 is a circuit diagram illustrating a first pixel and a second pixel included in a display panel according to embodiments, and FIG. 20 is a timing diagram for describing an example of an operation of a first pixel and a second pixel illustrated in FIG. 19.

Referring to FIG. 19, a display panel 200c′ according to embodiments may include a data line DL, a first pixel PX1c″ and a second pixel PX2c″. The first pixel PX1c″ may include a first-first transistor T1-1c″, a second-first transistor T2-1c, a third-first transistor T3-1c, a first capacitor CST1c, a fourth-first transistor T4-1c, a fifth-first transistor T5-1c, a sixth-first transistor T6-1c, a seventh-first transistor T7-1c, an eighth-first transistor T8-1c and a first light emitting element EL1c, and the second pixel PX2c″ may include a first-second transistor T1-2c″, a second-second transistor T2-2c, a third-second transistor T3-2c, a second capacitor CST2c, a fourth-second transistor T4-2c, a fifth-second transistor T5-2c, a sixth-second transistor T6-2c, a seventh-second transistor T7-2c, an eighth-second transistor T8-2c and a second light emitting element EL2c. The display panel 200c′ of FIG. 19 may have substantially the same configuration and substantially the same operation as a display panel 200c of FIG. 17, except that a second signal S2″ is an (N+2)-th initialization signal GI[n+2] for an (N+2)-th pixel row.

A first signal S1′ applied to the first-first transistor T1-1c′ may be a bypass signal GB[n] for a pixel row in which the first and second pixels PX1c″ and PX2c″ are arranged, and the second signal S2′ applied to the first-second transistor T1-2c′ may be the initialization signal GI[n+2] for another pixel row different from the pixel row. For example, as illustrated in FIGS. 19 and 20, in a case where the first and second pixels PX1c″ and PX2c″ are arranged in an N-th pixel row, the first signal S1′ may be an N-th bypass signal GB[n] for the N-th pixel row, and the second signal S2′ may be an (N+2)-th initialization signal GI[n+2] for an (N+2)-th pixel row. Further, as illustrated in FIG. 20, the first signal S1′, or the N-th bypass signal GB[n] may lead a writing signal GW[n] by about ½ horizontal time, an N-th initialization signal GI[n] may lead the writing signal GW[n] by about 3/2 horizontal time, an (N+1)-th initialization signal GI[n+1]) may lead the writing signal GW[n] by about ½ horizontal time, and the second signal S2′, or the (N+2)-th initialization signal GI[n+2] may lag the writing signal GW[n] by about ½ horizontal time. Accordingly, the first-first transistor T1-1c″, the second-first transistor T2-1c and the fourth-first transistor T4-1c may be turned on in a first period P1 of a data writing period DWP, and the first-second transistor T1-2c″, the second-second transistor T2-2c and the fourth-second transistor T4-2c may be turned on in a second period P2 of the data writing period DWP. Accordingly, the display panel 200c′ may perform a demultiplexing operation without a separate demultiplexer circuit.

Although FIGS. 19 and 20 illustrate an example in which the first signal S1′ is the N-th bypass signal GB[n] and the second signal S2′ is the (N+2)-th initialization signal GI[n+2], the first signal S1′ and the second signal S2′ according to embodiments are not limited to the example illustrated in FIGS. 19 and 20. For example, the first signal S1′ may be the (N+2)-th initialization signal GI[n+2] and the second signal S2′ may be the N-th bypass signal GB[n].

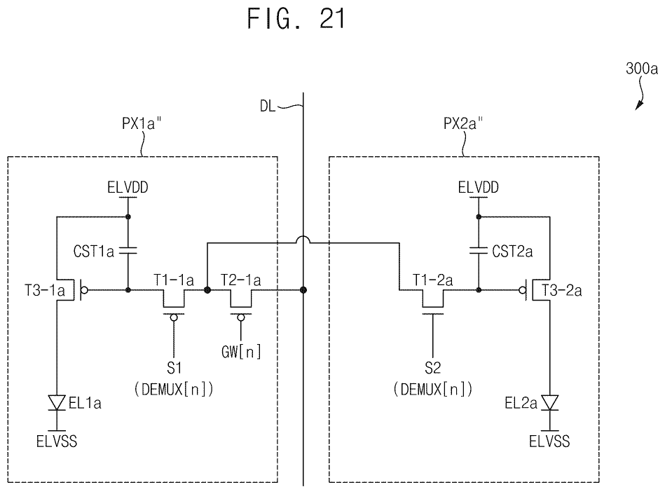

FIG. 21 is a circuit diagram illustrating a first pixel and a second pixel included in a display panel according to embodiments.

Referring to FIG. 21, a display panel 300a according to embodiments may include a data line DL, a first pixel PX1a″ and a second pixel PX2a″. The first pixel PX1a″ may include a first-first transistor T1-1a, a second-first transistor T2-1a, a third-first transistor T3-1a, a first capacitor CST1a and a first light emitting element EL1a, and the second pixel PX2a may include a first-second transistor T1-2a, a third-second transistor T3-2a, a second capacitor CST2a and a second light emitting element EL2a. The display panel 300a of FIG. 21 may have substantially the same configuration and substantially the same operation as a display panel 100a of FIG. 3, except that the second pixel PX2a″ may not include a transistor corresponding to the second-second transistor T2-2a FIG. 3, and the second-first transistor T2-1a may be connected to both of the first-first transistor T1-1a and the first-second transistor T1-2a.

The second-first transistor T2-1a included in the first pixel PX1a″ may be connected not only to the first-first transistor T1-1a of the first pixel PX1a″ but also to the first-second transistor T1-2a of the second pixel PX2a″. Thus, the second-first transistor T2-1a which receives a third signal, or a writing signal GW[n] may be shared by the first pixel PX1a″ and the second pixel PX2a″. In some embodiments, the second-first transistor T2-1a may include a gate which receives the writing signal GW[n], a first terminal connected to the data line DL, and a second terminal connected to both of the first-first transistor T1-1a and the first-second transistor T1-2a. Although FIG. 21 illustrates an example in which the first pixel PX1a″ includes the second-first transistor T2-1a and the second pixel PX2a″ does not include the second-second transistor, in other embodiments, the first pixel PX1a″ may not include the second-first transistor T2-1a and the second pixel PX2a″ may include the second-second transistor shared by the first pixel PX1a″ and the second pixel PX2a″.

FIG. 22 is a circuit diagram illustrating a first pixel and a second pixel included in a display panel according to embodiments.

Referring to FIG. 22, a display panel 300b according to embodiments may include a data line DL, a first pixel PX1c′″ and a second pixel PX2c″. The first pixel PX1c″′ may include a first-first transistor T1-1c, a second-first transistor T2-1c, a third-first transistor T3-1c, a first capacitor CST1c, a fourth-first transistor T4-1c, a fifth-first transistor T5-1c, a sixth-first transistor T6-1c, a seventh-first transistor T7-1c, an eighth-first transistor T8-1c and a first light emitting element EL1c, and the second pixel PX2c″′ may include a first-second transistor T1-2c, a third-second transistor T3-2c, a second capacitor CST2c, a fourth-second transistor T4-2c, a fifth-second transistor T5-2c, a sixth-second transistor T6-2c, a seventh-second transistor T7-2c, an eighth-second transistor T8-2c and a second light emitting element EL2c. The display panel 300b of FIG. 22 may have substantially the same configuration and substantially the same operation as a display panel 100c of FIG. 7, except that the second pixel PX2c′″ may not include a transistor corresponding to the second-second transistor T2-2c of FIG. 7, and the second-first transistor T2-1c may be connected to both the first-first transistor T1-1c and the first-second transistor T1-2c.

The second-first transistor T2-1c included in the first pixel PX1c′″ may be connected not only to the first-first transistor T1-1c of the first pixel PX1c′″ but also to the first-second transistor T1-2c of the second pixel PX2c′″. Thus, the second-first transistor T2-1c which receives a third signal, or a writing signal GW[n] may be shared by the first pixel PX1c″′ and the second pixel PX2c″. Although FIG. 22 illustrates an example in which the first pixel PX1c′″ includes the second-first transistor T2-1c and the second pixel PX2c″ does not include the second-second transistor, in other embodiments, the first pixel PX1c″ may not include the second-first transistor T2-1c and the second pixel PX2c′″ may include the second-second transistor shared by the first pixel PX1c″ and the second pixel PX2c″.

Although FIG. 21 illustrates an example in which the second-first transistor T2-1a is shared in the display panel 100a of FIG. 3, and FIG. 22 illustrates an example in which the second-first transistor T2-1c is shared in the display panel 100c of FIG. 7, the second-first transistor or the second-second transistor may be shared by two adjacent pixels in any display panel according to embodiments.

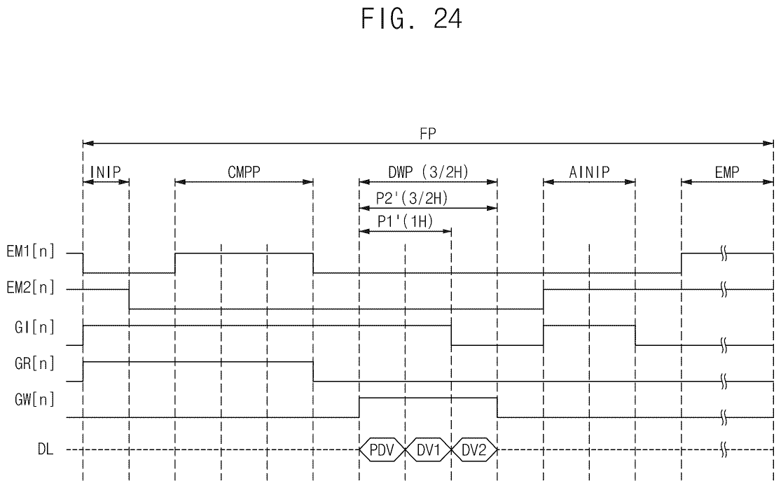

FIG. 23 is a circuit diagram illustrating a first pixel and a second pixel included in a display panel according to embodiments, and FIG. 24 is a timing diagram for describing an example of an operation of a first pixel and a second pixel illustrated in FIG. 23.

Referring to FIG. 23, a display panel 400 according to embodiments may include a data line DL, a first pixel PX1e and a second pixel PX2e. The first pixel PX1e may include a first transistor T1e, a second-first transistor T2-1e, a third-first transistor T3-1d, a first capacitor CST1d, a third capacitor CHOLD1, a fourth-first transistor T4-1d, a fifth-first transistor T5-1d, a sixth-first transistor T6-1d, a seventh-first transistor T7-1d and a first light emitting element EL1d, and the second pixel PX2e may include a second-second transistor T2-2e, a third-second transistor T3-2d, a second capacitor CST2d, a fourth capacitor CHOLD2, a fourth-second transistor T4-2d, a fifth-second transistor T5-2d, a sixth-second transistor T6-2d, a seventh-second transistor T7-2d and a second light emitting element EL2d. The display panel 400 of FIG. 23 may have a similar configuration and a similar operation to a display panel 100d of FIG. 9, except that the first pixel PX1e may include the first transistor T1e which receives a first signal S1, the second pixel PX2e may not include the first transistor T1e (or a first-second transistor), a data writing operation for the first pixel PX1e may be performed in a portion of a data writing period, and a data writing operation for the second pixel PX2e may be performed in the entire period of the data writing period.

The first transistor T1e of the first pixel PX1e may be connected in series with the second-first transistor T2-1e in a path from the data line DL to the first capacitor CST1d. The first transistor T1e may receive the first signal S1 having a second level (e.g., a high level) in a portion of the data writing period and have a first level (e.g., a low level) in the remaining portion of the data writing period. In some embodiments, as illustrated in FIGS. 23 and 24, the first transistor T1e may receive an initialization signal GI[n] as the first signal S1, but is not limited thereto. In other embodiments, the first transistor T1e may receive, as the first signal S1, a reference signal (e.g., an (N+1)-th reference signal) for another pixel row different from a pixel row in which the first and second pixels PX1e and PX2e are arranged.

The second-first transistor T2-1e of the first pixel PX1e may be connected in series with the first transistor T1e, and may be turned on in response to a writing signal GW[n] during a data writing period. The second-second transistor T2-2e of the second pixel PX2e may be directly connected to the data line DL, and may be turned on in response to the writing signal GW[n] during the data writing period.

Referring to FIGS. 23 and 24, a frame period FP may an initialization period INIP in which the first, second, third and fourth capacitors CST1d, CST2d, CHOLD1 and CHOLD2 are initialized, a compensation period CMPP in which threshold voltages of the third-first and third-second transistors T3-1d and T3-2d are compensated, the data writing period DWP′ in which data voltages DV1 and DV2 are written to the first and second pixels PX1e and PX2e, an anode initialization period AINIP in which the first and second light emitting elements EL1d and EL2d are initialized, and an emission period EMP in which the first and second light emitting elements EL1d and EL2d emit light. In some embodiments, the writing signal GW[n] may have an on-level or the second level (e.g., the high level) for about 3/2 horizontal time 3/2H, and the data writing period DWP′ in which the writing signal GW[n] has the on-level may have a time length of about 3/2 horizontal time 3/2H. Further, the writing signal GW[n] may be sequentially applied while being shifted by about 1 horizontal time 1H. Thus, data write periods DWP′ for adjacent pixel rows may partially overlap each other. For example, in a case where the first and second pixels PX1e and PX2e are arranged in an N-th pixel row, an initial ½ horizontal time of the data write period DWP′ for the N-th pixel row may overlap the data write period DWP′ for an (N−1)-th pixel row. In this case, a previous data voltage PDV for a pixel included in the (N−1)-th pixel row may be applied to the data line DL during the initial ½ horizontal time of the data writing period DWP′, a first data voltage DV1 for the first pixel PX1e may be applied to the data line DL during a middle ½ horizontal time of the data writing period DWP′, and a second data voltage DV2 for the second pixel PX2e may be applied to the data line DL during a last ½ horizontal time of the data writing period DWP′.

In a first period P1′ of the data writing period DWP′, the initialization signal GI[n] and the writing signal GW[n] may have the high level. In some embodiments, the first period P1′ of the data writing period DWP′ may have a time length of about 1 horizontal time 1H, but is not limited thereto. Thus, in the first period P1′ of the data writing period DWP′, the first transistor T1e, the second-first transistor T2-1e and the second-second transistor T2-2e may be turned on. In the remaining period of the data writing period DWP′, the writing signal GW[n] may have the high level, and the initialization signal GI[n] may have the low level. Thus, in the remaining period of the data writing period DWP′, the first transistor T1e may be turned off, and the second-first transistor T2-1e and the second-second transistor T2-2e may be turned on. Accordingly, since the first transistor T1e and the second-first transistor T2-1e may be turned on during the first period P1′ of the data writing period DWP′, the first capacitor CST1d may be connected to the data line DL through the first transistor T1e and the second-first transistor T2-1e during the first period P1′ of the data writing period DWP′, and the data writing operation for the first pixel PX1e may be performed during the first period P1′ of the data writing period DWP′. Meanwhile, since the first data voltage DV1 is applied to the data line DL during the last ½ horizontal time of the first period P1′ of the data writing period DWP′, the first capacitor CST1d may store the first data voltage DV1 at a first electrode of the first capacitor CST1d. Further, since the second-second transistor T2-2e is turned on during the second period P2′ of the data writing period DWP′, or during the entire period of the data writing period DWP′, the second capacitor CST2d may be connected to the data line DL through the second-second transistor T2-2e during the second period P2′ of the data writing period DWP′, and the data writing operation for the second pixel PX2e may be performed during the second period P2′ of the data writing period DWP′, or during the entire period of the data writing period DWP′. Meanwhile, since the second data voltage DV2 is applied to the data line DL during the last ½ horizontal time of the data writing period DWP′, the second capacitor CST2d may store the second data voltage DV2 at a first electrode of the second capacitor CST2d. Accordingly, the display panel 400 may perform a demultiplexing operation without a separate demultiplexer circuit.

FIG. 25 is a diagram illustrating a display panel according to embodiments.

Referring to FIG. 25, to reduce the number of output channels of a data driver 570, a conventional display panel 510 includes a demultiplexer circuit 512 connected to the data driver 570 through a spider unit 514. However, in a display panel 560 according to embodiments, data lines DL1, . . . , DLN/2 of the display panel 560 may be connected to the data driver 570 through the spider unit 564 without the demultiplexer circuit 512, and the display panel 560 may perform a demultiplexing operation using at least one transistor included in first and second pixels PX1 and PX2 without the demultiplexer circuit 512. Accordingly, a size of a non-display region of the display panel 560 according to embodiments may be reduced compared with a size of a non-display region of the conventional display panel 510 including the demultiplexer circuit 512.

Further, in the conventional display panel 510, power may be consumed to drive the demultiplexer circuit 512. However, in the display panel 560 according to embodiments, the power for driving the demultiplexer circuit 512 may not be consumed, and thus power consumption of the display panel 510 and a display device including the display panel 510 may be reduced.

In addition, the conventional display panel 510 may include one data line DL1, DL2, . . . , DLN for each column of pixels PX. That is, in the conventional display panel 510, the number of data lines DL1, DL2, . . . , DLN may correspond to the number of columns of the pixels PX. However, the display panel 560 according to embodiments may include one data line DL1, . . . , DLN/2 for two adjacent columns of the pixels PX1 and PX2. That is, in the display panel 560 according to embodiments, the number of data lines DL1, . . . , DLN/2 may correspond to half the number of columns of the pixels PX1 and PX2. Accordingly, the number of data lines DL1, . . . , DLN/2 of the display panel 560 according to embodiments may be reduced to half the number of data lines DL1, DL2, . . . , DLN of the conventional display panel 510.

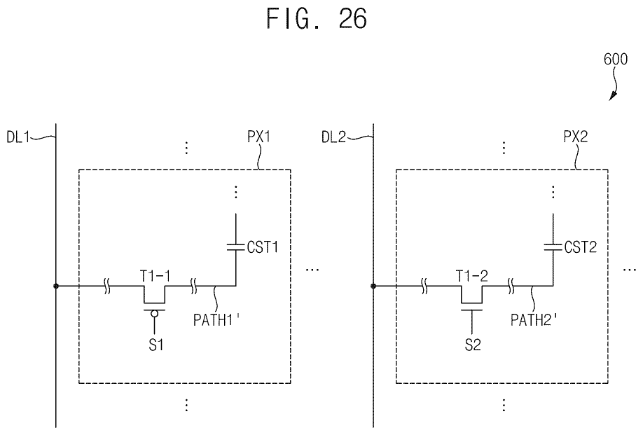

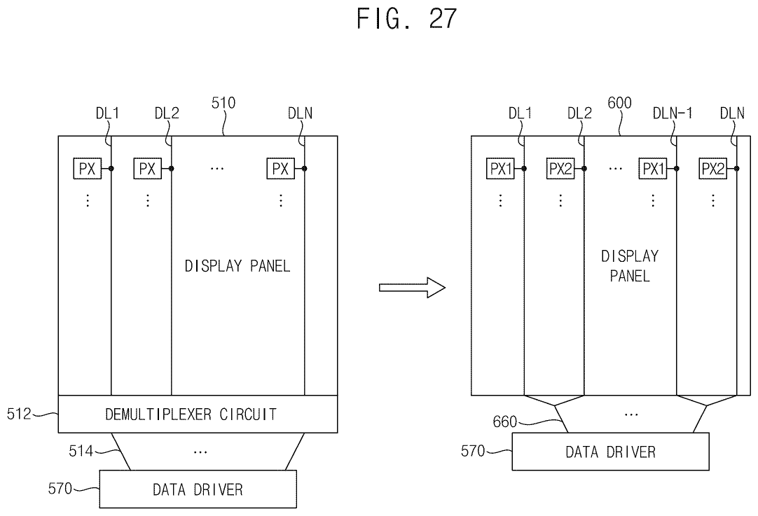

FIG. 26 is a circuit diagram illustrating a first pixel and a second pixel included in a display panel according to embodiments, and FIG. 27 is a diagram illustrating a display panel including a first pixel and a second pixel illustrated in FIG. 26.

Referring to FIG. 26, a display panel 600 according to embodiments may include a first data line DL1, a second data line DL2, a first pixel PX1 connected to the first data line DL1, and a second pixel PX2 connected to the second data line DL2. The display panel 600 of FIG. 26 may have substantially the same configuration and substantially the same operation as a display panel 100 of FIG. 1, except that the first and second pixels PX1 and PX2 are connected to different data lines DL1 and DL2.

The first pixel PX1 may store a first data voltage of the first data line DL1 in a first capacitor CST1 in a first period of a data writing period, and the second pixel PX2 may store a second data voltage of the second data line DL2 in a second capacitor CST2 in a second period of the data writing period. To perform these operations, the first pixel PX1 may include a first-first transistor T1-1 located in a first path PATH1′ from the first data line DL1 to the first capacitor CST1, and the second pixel PX2 may include a first-second transistor T1-2 located in a second path PATH2′ from the second data line DL2 to the second capacitor CST2. The first-first transistor T1-1 may be turned on in response to a first signal S1 during the first period of the data writing period, and the first-second transistor T1-2 may be turned on in response to the second signal S2 during the second period of the data writing period. Accordingly, the display panel 600 may perform a demultiplexing operation without a separate demultiplexer circuit.

As illustrated in FIG. 27, the number of data lines DL1, DL2, . . . , DLN−1 and DLN of the display panel 600 may be substantially the same as the number of data lines DL1, DL2, DLN of the conventional display panel 510. However, since the data lines DL1, DL2, . . . , DLN−1 and DLN of the display panel 600 are connected to the data driver 570 through the spider unit 660 without the demultiplexer circuit 512, the size of the non-display region of the display panel 600 according to embodiments may be reduced compared with the size of the non-display region of the conventional display panel 510 including the demultiplexer circuit 512. Further, in the display panel 600 according to embodiments, since power for driving the demultiplexer circuit 512 is not consumed, the power consumption of the display panel 600 and the display device including the display panel 600 may be reduced.

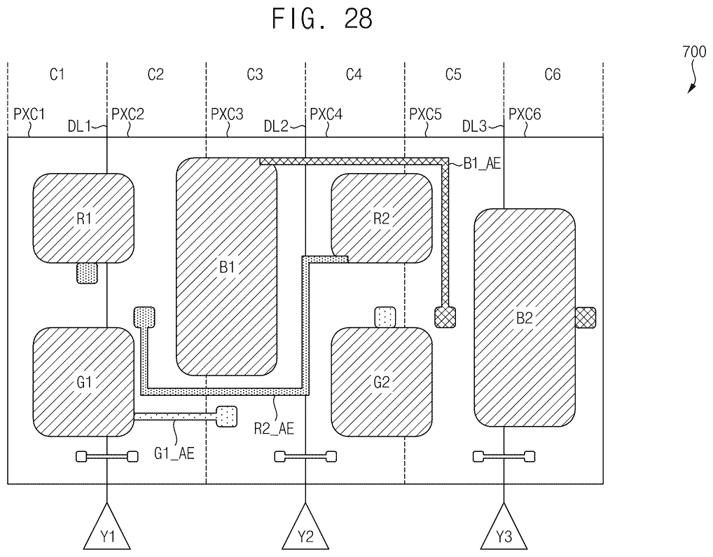

FIG. 28 is a diagram illustrating a portion of a display panel according to embodiments.

Referring to FIG. 28, a display panel 700 according to embodiments may include first, second and third data lines DL1, DL2 and DL3, first, second, third, fourth, fifth and sixth pixel circuits PXC1, PXC2, PXC3, PXC4, PXC5 and PXC6, first and second red light emitting elements R1 and R2, first and second green light emitting elements G1 and G2 and first and second blue light emitting elements B1 and B2. Although FIG. 28 illustrates a portion of the display panel 700 in which six pixel circuits PXC1 through PXC6 and six light emitting elements R1, R2, G1, G2, B1 and B2 are arranged, the display panel 700 may include more than six pixel circuits and more than six light emitting elements.

The first pixel circuit PXC1 may be located in a first column C1, the second pixel circuit PXC2 may be located in a second column C2, the third pixel circuit PXC3 may be located in a third column C3, the fourth pixel circuit PXC4 may be located in a fourth column C4, the fifth pixel circuit PXC5 may be located in a fifth column C5, and the sixth pixel circuit PXC6 may be located in a sixth column C6. Further, the first data line DL1 may be located between the first column C1 and the second column C2, and may be connected to the first pixel circuit PXC1 located in the first column C1 and the second pixel circuit PXC2 located in the second column C2. The second data line DL2 may be located between the third column C3 and the fourth column C4, and may be connected to the third pixel circuit PXC3 located in the third column C3 and the fourth pixel circuit PXC4 located in the fourth column C4. The third data line DL3 may be located between the fifth column C5 and the sixth column C6, and may be connected to the fifth pixel circuit PXC5 located in the fifth column C5 and the sixth pixel circuit PXC6 located in the sixth column C6. Thus, a first output channel Y1 of a data driver may provide data voltages to the first pixel circuit PXC1 and the second pixel circuit PXC2 through the first data line DL1, a second output channel Y2 of the data driver may provide data voltages to the third pixel circuit PXC3 and the fourth pixel circuit PXC4 through the second data line DL2, and a third output channel Y3 of the data driver may provide data voltages to the fifth pixel circuit PXC5 and the sixth pixel circuit PXC6 through the third data line DL3.

The first red light emitting element R1 may be located in the first and second columns C1 and C2, and may be connected to the first pixel circuit PXC1 located in the first column C1. Further, the second red light emitting element R2 may be located in the fourth and fifth columns C4 and C5, and may be connected to the second pixel circuit PXC2 located in the second column C2 through an anode extension R2_AE of the second red light emitting element R2. Thus, the first red light emitting element R1 and the first pixel circuit PXC1 may form a first red pixel, and the second red light emitting element R2 and the second pixel circuit PXC2 may form a second red pixel. According to embodiments, the first and second red pixels may respectively correspond to first and second pixels described above with reference to FIGS. 1 through 27.

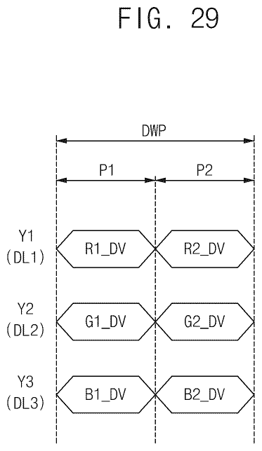

Accordingly, as illustrated in FIG. 29, the first output channel Y1 may output data voltages R1_DV and R2_DV for the first and second red light emitting elements R1 and R2 having the same color in a data writing period DWP. For example, the first output channel Y1 may provide the data voltage R1_DV for the first red light emitting element R1 to the first pixel circuit PXC1 through the first data line DL1 in a first period P1 of the data writing period DWP, and may provide the data voltage R2_DV for the second red light emitting element R2 to the second pixel circuit PXC2 through the first data line DL1 in a second period P2 of the data writing period DWP. The first pixel circuit PXC1 may drive the first red light emitting element R1 based on the data voltage R1_DV for the first red light emitting element R1, and the second pixel circuit PXC2 may drive the second red light emitting element R2 based on the data voltage R2_DV for the second red light emitting element R2.

Further, the first green light emitting element G1 may be located in the first and second columns C1 and C2 (e.g., below the first red light emitting element R1), and may be connected to the third pixel circuit PXC3 located in the third column C3 through an anode extension G1_AE of the first green light emitting element G1. The second green light emitting element G2 may be located in the fourth and fifth columns C4 and C5 (e.g., below the second red light emitting element R2), and may be connected to the fourth pixel circuit PXC4 located in the fourth column C4. Thus, the first green light emitting element G1 and the third pixel circuit PXC3 may form a first green pixel, and the second green light emitting element G2 and the fourth pixel circuit PXC4 may form a second green pixel. According to embodiments, the first and second green pixels may respectively correspond to the first and second pixels described above with reference to FIGS. 1 through 27.

Accordingly, as illustrated in FIG. 29, the second output channel Y2 may output data voltages G1_DV and G2_DV for the first and second green light emitting elements G1 and G2 having the same color in the data writing period DWP. For example, the second output channel Y2 may provide the data voltage G1_DV for the first green light emitting element G1 to the third pixel circuit PXC3 through the second data line DL2 in the first period P1 of the data writing period DWP, and may provide the data voltage G2_DV for the second green light emitting element G2 to the fourth pixel circuit PXC4 through the second data line DL2 in the second period P2 of the data writing period DWP. The third pixel circuit PXC3 may drive the first green light emitting element G1 based on the data voltage G1_DV for the first green light emitting element G1, and the fourth pixel circuit PXC4 may drive the second green light emitting element G2 based on the data voltage G2_DV for the second green light emitting element G2.

Further, the first blue light emitting element B1 may be located in the second and third columns C2 and C3, and may be connected to the fifth pixel circuit PXC5 located in the fifth column C5 through an anode extension B1_AE of the first blue light emitting element B1. The second blue light emitting element B2 may be located in the fifth and sixth columns C5 and C6, and may be connected to the sixth pixel circuit PXC6 located in the sixth column C6. Thus, the first blue light emitting element B1 and the fifth pixel circuit PXC5 may form a first blue pixel, and the second blue light emitting element B2 and the sixth pixel circuit PXC6 may form a second blue pixel. According to embodiments, the first and second blue pixels may respectively correspond to the first and second pixels described above with reference to FIGS. 1 through 27.

Accordingly, as illustrated in FIG. 29, the third output channel Y3 may output data voltages B1_DV and B2_DV for the first and second blue light emitting elements B1 and B2 having the same color in the data writing period DWP. For example, the third output channel Y3 may provide the data voltage B1_DV for the first blue light emitting element B1 to the fifth pixel circuit PXC5 through the third data line DL3 in the first period P1 of the data writing period DWP, and may provide the data voltage B2_DV for the second blue light emitting element B2 to the sixth pixel circuit PXC6 through the third data line DL3 in the second period P2 of the data writing period DWP. The fifth pixel circuit PXC5 may drive the first blue light emitting element B1 based on the data voltage B1_DV for the first blue light emitting element B1, and the sixth pixel circuit PXC6 may drive the second blue light emitting element B2 based on the data voltage B2_DV for the second blue light emitting element B2.

As described above, in the display panel 700 according to embodiments, the second red light emitting element R2 may be connected to the second pixel circuit PXC2 through the anode extension R2_AE of the second red light emitting element R2, the first green light emitting element G1 may be connected to the third pixel circuit PXC3 through the anode extension G1_AE of the first green light emitting element G1, and the first blue light emitting element B1 may be connected to the fifth pixel circuit PXC5 through the anode extension B1_AE of the first blue light emitting element B1. Accordingly, in the data writing period DWP, the data voltages R1_DV and R2_DV for the first and second red light emitting elements R1 and R2 having the same color may be applied to the first data line DL1, the data voltages G1_DV and G2_DV for the first and second green light emitting elements G1 and G2 having the same color may be applied to the second data line DL2, and the data voltages B1_DV and B2_DV for the first and second blue light emitting elements B1 and B2 having the same color may be applied to the third data line DL3. Thus, compared with a display panel in which data voltages for light emitting elements having different colors are applied to each data line in a data writing period, power consumption of a display device including the display panel 700 according to embodiments may be reduced.

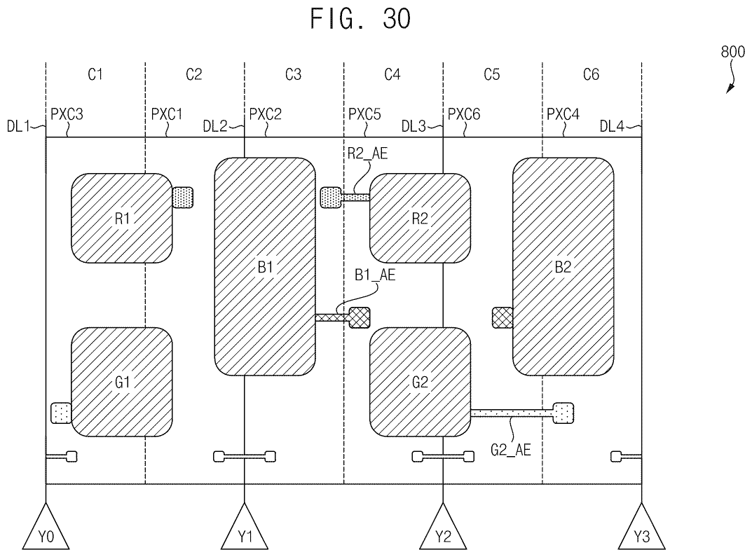

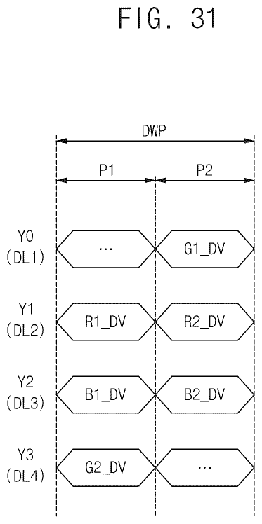

FIG. 30 is a diagram illustrating a portion of a display panel according to embodiments, and FIG. 31 is a timing diagram for describing an example of data voltages provided to a display panel illustrated in FIG. 30.

Referring to FIG. 30, a display panel 800 according to embodiments may include first, second, third and fourth data lines DL1, DL2, DL3 and DL4, first, second, third, fourth, fifth and sixth pixel circuits PXC1, PXC2, PXC3, PXC4, PXC5 and PXC6, first and second red light emitting elements R1 and R2, first and second green light emitting elements G1 and G2 and first and second blue light emitting elements B1 and B2.

The first pixel circuit PXC1 may be located in a second column C2, the second pixel circuit PXC2 may be located in a third column C3, the third pixel circuit PXC3 may be located in a first column C1, the fourth pixel circuit PXC4 may be located in a sixth column C6, the fifth pixel circuit PXC5 may be located in a fourth column C4, and the sixth pixel circuit PXC6 may be located in a fifth column C5. Further, the first data line DL1 may be located adjacent to the first column C1, and may be connected to the third pixel circuit PXC3 located in the first column C1. The second data line DL2 may be located between the second column C2 and the third column C3, and may be connected to the first pixel circuit PXC1 located in the second column C2 and the second pixel circuit PXC2 located in the third column C3. The third data line DL3 may be located between the fourth column C4 and the fifth column C5, and may be connected to the fifth pixel circuit PXC5 located in the fourth column C4 and the sixth pixel circuit PXC6 located in the fifth column C5. The fourth data line DL4 may be located adjacent to the sixth column C6, and may be connected to the fourth pixel circuit PXC4 located in the sixth column C6. Thus, a zeroth output channel Y0 of a data driver may provide a data voltage to the third pixel circuit PXC3 through the first data line DL1, a first output channel Y1 of the data driver may provide data voltages to the second pixel circuit PXC2 and the third pixel circuit PXC3 through the second data line DL2, a second output channel Y2 of the data driver may provide data voltages to the fifth pixel circuit PXC5 and the sixth pixel circuit PXC6 through the third data line DL3, and a third output channel Y3 of the data driver may provide a data voltage to the fourth pixel circuit PXC4 through the fourth data line DL4.

The first red light emitting element R1 may be located in the first and second columns C1 and C2, and may be connected to the first pixel circuit PXC1 located in the second column C2. The second red light emitting element R2 may be located in the fourth and fifth columns C4 and C5, and may be connected to the second pixel circuit PXC2 located in the third column C3 through an anode extension R2_AE of the second red light emitting element R2. Thus, the first red light emitting element R1 and the first pixel circuit PXC1 may form a first red pixel, and the second red light emitting element R2 and the second pixel circuit PXC2 may form a second red pixel. According to embodiments, the first and second red pixels may respectively correspond to first and second pixels described above with reference to FIGS. 1 through 27. Accordingly, as illustrated in FIG. 31, the first output channel Y1 may output data voltages R1_DV and R2_DV for the first and second red light emitting elements R1 and R2 having the same color in a data writing period DWP.

Further, the first blue light emitting element B1 may be located in the second and third columns C2 and C3, and may be connected to the fifth pixel circuit PXC5 located in the fourth column C4 through an anode extension B1_AE of the first blue light emitting element B1. The second blue light emitting element B2 may be located in the fifth and sixth columns C5 and C6, and may be connected to the sixth pixel circuit PXC6 located in the fifth column C5. Thus, the first blue light emitting element B1 and the fifth pixel circuit PXC5 may form a first blue pixel, and the second blue light emitting element B2 and the sixth pixel circuit PXC6 may form a second blue pixel. According to embodiments, the first and second blue pixels may respectively correspond to the first and second pixels described above with reference to FIGS. 1 through 27. Accordingly, as illustrated in FIG. 31, the second output channel Y2 may output data voltages B1_DV and B2_DV for the first and second blue light emitting elements B1 and B2 having the same color in the data writing period DWP.

Further, the first green light emitting element G1 may be located in the first and second columns C1 and C2, and may be connected to the third pixel circuit PXC3 located in the first column C1. Accordingly, the first green light emitting element G1 and the third pixel circuit PXC3 may form a first green pixel. Although it is not illustrated in FIG. 30, the first data line DL1 may be further connected to another pixel circuit arranged on the left side of the third pixel circuit PXC3, and the other pixel circuit may drive a green light emitting element. Accordingly, as illustrated in FIG. 31, the zeroth output channel Y0 may output data voltages G1_DV for green light emitting elements G1 in the data writing period DWP.

In addition, the second green light emitting element G2 may be located in the fourth and fifth columns C4 and C5, and may be connected to the fourth pixel circuit PXC4 located in the sixth column C6 through an anode extension G2_AE of the second green light emitting element G2. Thus, the second green light emitting element G2 and the fourth pixel circuit PXC4 can form a second green pixel. Although it is not illustrated in FIG. 30, the fourth data line DL4 may be further connected to another pixel circuit arranged on the right side of the fourth pixel circuit PXC4, and the another pixel circuit may drive a green light emitting element. Accordingly, as illustrated in FIG. 31, the third output channel Y3 may output data voltages G2_DV for green light emitting elements G2 in the data writing period DWP.

The display panel 800 of FIG. 30 may include one more data line compared with a display panel 700 of FIG. 28, but lengths of the anode extensions R2_AE, B1_AE and G2_AE included in the display panel 800 of FIG. 30 may be reduced compared with lengths of the anode extensions R2_AE, G1_AE and B1_AE included in the display panel 700 of FIG. 28. Further, data voltages for light emitting elements having the same color may be applied to each data line in the data writing period DWP, and the power consumption of the display device including the display panel 800 according to embodiments may be reduced.

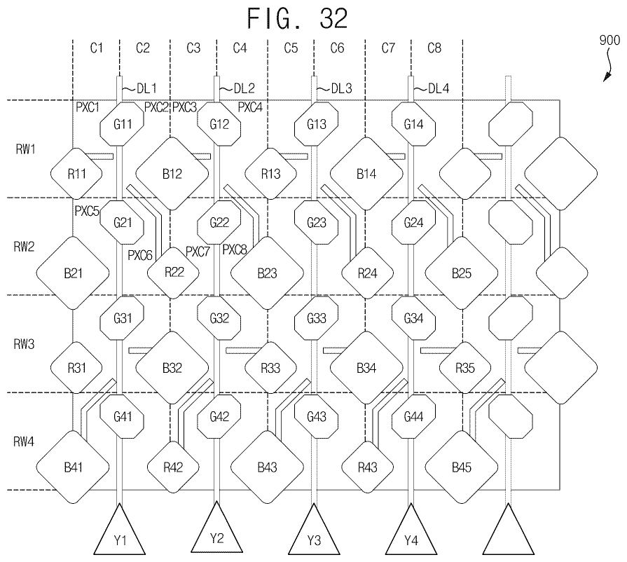

FIG. 32 is a diagram illustrating a portion of a display panel according to embodiments.

Referring to FIG. 32, a display panel 900 according to embodiments may include a plurality of data lines DL1, DL2, DL3 and DL4, a plurality of pixel circuits PXC1, PXC2, PXC3, PXC4, PXC5, PXC6, PXC7 and PXC8, a plurality of red light emitting elements R11, R13, R22, R24, R31, R33, R35, R42 and R44, a plurality of green light emitting elements G11, G12, G13, G14, G21, G22, G23, G24, G31, G32, G33, G34, G41, G42, G43 and G44, and a plurality of blue light emitting elements B12, B14, B21, B23, B25, B32, B34, B41, B43 and B45.

A first data line DL1 may be located between a first column C1 and a second column C2, and may be connected to a first output channel Y1 of a data driver. A second data line DL2 may be located between a third column C3 and a fourth column C4, and may be connected to a second output channel Y2 of the data driver. A third data line DL3 may be located between a fifth column C5 and a sixth column C6, and may be connected to a third output channel Y3 of the data driver. A fourth data line DL4 may be located between a seventh column C7 and an eighth column C8, and may be connected to a fourth output channel Y4 of the data driver.

In some embodiments, red, green, blue and green light emitting elements R11, G11, B12, G12, R13, G13, B14 and G14 may be sequentially arranged in a first row RW1, blue, green, red and green light emitting elements B21, G21, R22, G22, B23, G23, R24, G24 and B25 may be sequentially arranged in a second row RW2, red, green, blue and green light emitting elements R31, G31, B32, G32, R33, G33, B34, G34 and R35 may be sequentially arranged in a third row RW3, and blue, green, red and green light emitting elements B41, G41, R42, G42, B43, G43, R44, G44 and B45 may be sequentially arranged a fourth row RW4. Further, in the display panel 900, one red light emitting element (e.g., R11), two red light emitting elements (e.g., G11 and G21) and one blue light emitting element (e.g., B12) adjacent to each other may be arranged in a diamond shape.

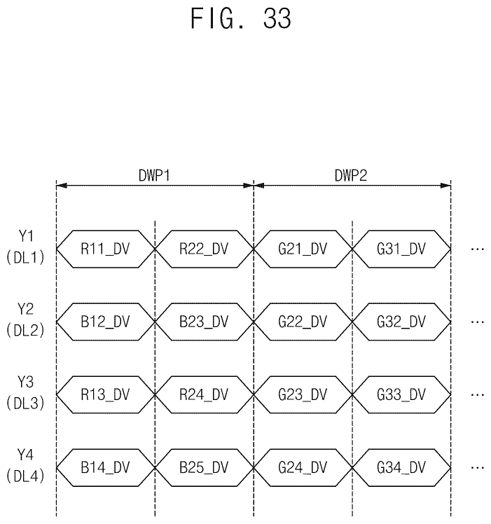

Further, in some embodiments, a first pixel circuit PXC1 located in the first row RW1 and the first column C1 may be connected to a first red light emitting element R11 located in the first row RW1 and the first column C1, and a second pixel circuit PXC2 located in the first row RW1 and the second column C2 may be connected to a second red light emitting element R22 located in the second row RW2 and the second and third columns C2 and C3 through an anode extension of the second red light emitting element R22. Thus, the first red light emitting element R11 and the first pixel circuit PXC1 may form a first red pixel, and the second red light emitting element R22 and the second pixel circuit PXC2 may form a second red pixel. According to embodiments, the first and second red pixels may respectively correspond to first and second pixels described above with reference to FIGS. 1 through 27. Further, the first and second pixel circuits PXC1 and PXC2 may be connected to the first data line DL1 located between the first column C1 and the second column C2. Accordingly, as illustrated in FIG. 33, the first output channel Y1 connected to the first data line DL1 may output data voltages R11_DV and R22_DV for the first and second red light emitting elements R11 and R22 having the same color in a first data writing period DWP1.

A third pixel circuit PXC3 located in the first row RW1 and the third column C3 may be connected to a first blue light emitting element B12 located in the first row RW1 and the second and third columns C2 and C3, and a fourth pixel circuit PXC4 located in the first row RW1 and the fourth column C4 may be connected to a second blue light emitting element B23 located in the second row RW2 and the fourth and fifth columns C4 and C5 through an anode extension of the second blue light emitting element B23. Thus, the first blue light emitting element B12 and the third pixel circuit PXC3 may form a first blue pixel, and the second blue light emitting element B23 and the fourth pixel circuit PXC4 may form a second blue pixel. According to embodiments, the first and second blue pixels may respectively correspond to the first and second pixels described above with reference to FIGS. 1 through 27. Further, the third and fourth pixel circuits PXC3 and PXC4 may be connected to the second data line DL2 located between the third column C3 and the fourth column C4. Accordingly, as illustrated in FIG. 33, the second output channel Y2 connected to the second data line DL2 may output data voltages B12_DV and B23_DV for the first and second blue light emitting elements B12 and B23 having the same color in the first data writing period DWP1.

A fifth pixel circuit PXC5 located in the second row RW2 and the first column C1 may be connected to a first green light emitting element G21 located in the second row RW2 and the first and second columns C1 and C2, and a sixth pixel circuit PXC6 located in the second row RW2 and the second column C2 may be connected to a second green light emitting element G31 located in the third row RW3 and the first and second columns C1 and C2. Thus, the first green light emitting element G21 and the fifth pixel circuit PXC5 may form a first green pixel, and the second green light emitting element G31 and the sixth pixel circuit PXC6 may form a second green pixel. According to embodiments, the first and second green pixels may respectively correspond to the first and second pixels described above with reference to FIGS. 1 through 27. Further, the fifth and sixth pixel circuits PXC5 and PXC6 may be connected to the first data line DL1 located between the first column C1 and the second column C2. Accordingly, as illustrated in FIG. 33, the first output channel Y1 connected to the first data line DL1 may output data voltages G21_DV and G31_DV for the first and second green light emitting elements G21 and G31 having the same color in a second data writing period DWP2.

A seventh pixel circuit PXC7 located in the second row RW2 and the third column C3 may be connected to a third green light emitting element G22 located in the second row RW2 and the third and fourth columns C3 and C4, and an eighth pixel circuit PXC8 located in the second row RW2 and the fourth column C4 may be connected to a fourth green light emitting element G32 located in the third row RW3 and the third and fourth columns C3 and C4. Thus, the third green light emitting element G22 and the seventh pixel circuit PXC7 may form a third green pixel, and the fourth green light emitting element G32 and the eighth pixel circuit PXC8 may form a fourth green pixel. According to embodiments, the third and fourth green pixels may respectively correspond to the first and second pixels described above with reference to FIGS. 1 through 27. Further, the seventh and eighth pixel circuits PXC7 and PXC8 may be connected to the second data line DL2 located between the third column C3 and the fourth column C4. Accordingly, as illustrated in FIG. 33, the second output channel Y2 connected to the second data line DL2 may output data voltages G22_DV and G32_DV for the third and fourth green light emitting elements G22 and G32 having the same color in the second data writing period DWP2.

Similarly, as illustrated in FIG. 33, the third output channel Y3 connected to the third data line DL3 may output data voltages R13_DV and R24_DV for the red light emitting elements R13 and R24 in the first data writing period DWP1, and may output data voltages G23_DV and G33_DV for the green light emitting elements G23 and G33 in the second data writing period DWP2. Further, the fourth output channel Y4 connected to the fourth data line DL4 may output data voltages B14_DV and B25_DV for blue light emitting elements B14 and B25 in the first data writing period DWP1, and may output data voltages G24_DV and G34_DV for green light emitting elements G24 and G34 in the second data writing period DWP2.

As described above, in the display panel 900 according to embodiments, data voltages for light emitting elements having the same color may be applied to each data line during each data writing period, and thus power consumption of a display device including the display panel 900 may be reduced.

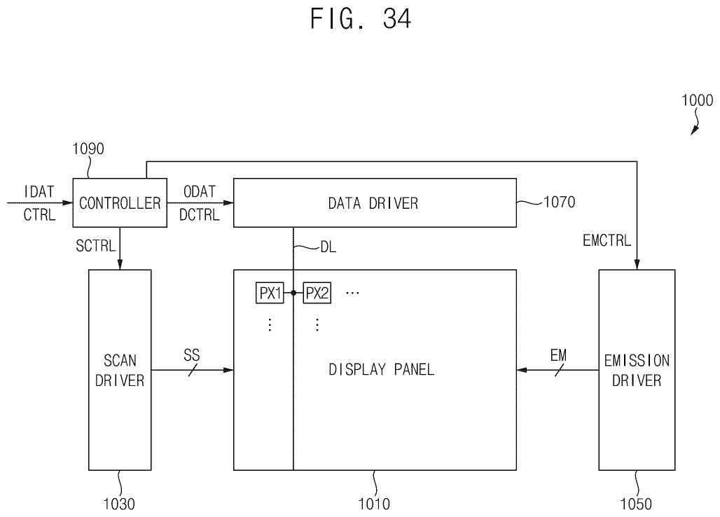

FIG. 34 is a block diagram illustrating a display device according to embodiments.

Referring to FIG. 34, a display device 1000 according to embodiments may include a display panel 1010 that includes a plurality of pixels PX1 and PX2, a scan driver 1030 that provides scan signals SS to the plurality of pixels PX1 and PX2, a data driver 1070 connected to the plurality of pixels PX1 and PX2 through a plurality of data lines DL, and a controller 1090 that controls the scan driver 1030 and the data driver 1070. In some embodiments, the display device 1000 may further include an emission driver 1050 that provides emission signals EM to the plurality of pixels PX1 and PX2.

The display panel 1010 may include a data line DL, a first pixel PX1 that stores a first data voltage of the data line DL in a first capacitor during a first period of a data writing period, and a second pixel PX2 that stores a second data voltage of the data line DL in a second capacitor during a second period of the data writing period. Further, in some embodiments, the first pixel PX1 may include a first-first transistor located in a first path from the data line DL to the first capacitor and turned on in response to a first signal during the first period of the data writing period, and the second pixel PX2 may include a first-second transistor located in a second path from the data line DL to the second capacitor and turned on in response to a second signal during the second period of the data writing period. Accordingly, the display panel 1010 may perform a demultiplexing operation without a demultiplexer circuit. According to embodiments, the display panel 1010 may be one of display panels described with reference to FIGS. 1 through 33.

The scan driver 1030 may generate the scan signals SS based on a scan control signal SCTRL received from the controller 1090, and may sequentially provide the scan signals SS to the plurality of pixels PX1 and PX2 on a row-by-row basis. In some embodiments, the scan control signal SCTRL may include, but is not limited to, a scan start signal and a scan clock signal. In some embodiments, the scan driver 1030 may provide, as the scan signals, the first signal, the second signal and a writing signal having an on-level during the data writing period to the first pixel PX1 and the second pixel PX2, but is not limited thereto. According to embodiments, the scan signals SS may include, but are not limited to, a writing signal GW[n], a demultiplexing signal DEMUX[n], an initialization signal GI[n], a bypass signal GB[n], a reference signal GR[n], etc., as described with reference to FIGS. 1 through 26. Further, in some embodiments, the scan driver 1030 may be integrated or formed in a display region or a peripheral region of the display panel 1010. In other embodiments, the scan driver 1030 may be implemented with one or more integrated circuits.

The emission driver 1050 may generate the emission signals EM based on an emission control signal EMCTRL received from the controller 1090, and may sequentially provide the emission signals EM to the plurality of pixels PX1 and PX2 on a row-by-row basis. In some embodiments, the emission control signal EMCTRL may include, but is not limited to, an emission start signal and an emission clock signal. Further, in some embodiments, the emission driver 1050 may be integrated or formed in the display region or the peripheral region of the display panel 1010. In other embodiments, the emission driver 1050 may be implemented with one or more integrated circuits.

The data driver 1070 may generate data voltages based on output image data ODAT and a data control signal DCTRL received from the controller 1090, and may provide the data voltages to the plurality of pixels PX1 and PX2 through the data lines DL. In some embodiments, the data control signal DCTRL may include, but is not limited to, an output data enable signal, a horizontal start signal and a load signal. In some embodiments, a single output channel of the data driver 1070 may provide the first data voltage to the first pixel PX1 through the data line DL, and may provide the second data voltage to the second pixel PX2 through the data line DL. Accordingly, the number of output channels of the data driver 1070 may be reduced compared with the number of output channels of a data driver of a display device that does not perform the demultiplexing operation. In some embodiments, the data driver 1070 and the controller 1090 may be implemented as a single integrated circuit, and the single integrated circuit may be referred to as a timing controller embedded data driver (“TED”) integrated circuit. In other embodiments, the data driver 1070 and the controller 1090 may be implemented as separate integrated circuits.

The controller 1090 (e.g., a timing controller) may receive input image data IDAT and a control signal CTRL from an external host processor (e.g., an application processor (“AP”), a graphics processor (“GPU”) or a graphics card). In some embodiments, the control signal CTRL may include, but is not limited to, a vertical synchronization signal, a horizontal synchronization signal, an input data enable signal, a master clock signal, etc. The controller 1090 may generate the output image data ODAT, the data control signal DCTRL, the scan control signal SCTRL and the emission control signal EMCTRL based on the input image data IDAT and the control signal CTRL. Further, the controller 1090 may control the scan driver 1030 by providing the scan control signal SCTRL to the scan driver 1030, may control the emission driver 1050 by providing the emission control signal EMCTRL to the emission driver 1050, and may control the data driver 1070 by providing the output image data ODAT and the data control signal DCTRL to the data driver 1070.

As described above, in the display device 1000 according to embodiments, the display panel 1010 may perform the demultiplexing operation without the demultiplexer circuit. Accordingly, a size of a non-display area of the display panel 1010 may be reduced, and the power consumption of the display device 1000 may be reduced.

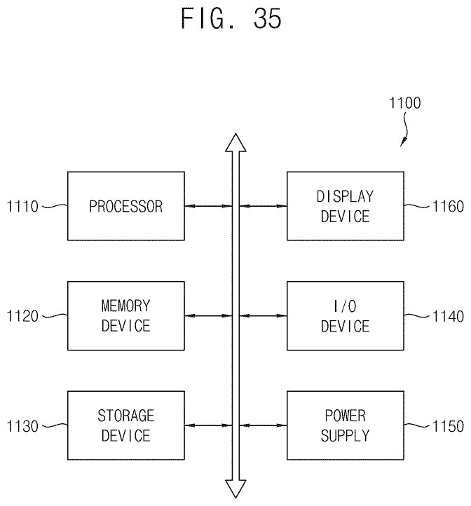

FIG. 35 is a block diagram illustrating an electronic device including a display device according to embodiments.

Referring to FIG. 35, an electronic device 1100 may include a processor 1110, a memory device 1120, a storage device 1130, an input/output (I/O) device 1140, a power supply 1150 and a display device 1160. The electronic device 1100 may further include a plurality of ports for communicating with a video card, a sound card, a memory card, a universal serial bus (“USB”) device, other electric devices, etc.

The processor 1110 may perform various computing functions or tasks. The processor 1110 may be an application processor (“AP”), a micro-processor, a central processing unit (“CPU”), etc. The processor 1110 may be coupled to other components via an address bus, a control bus, a data bus, etc. Further, in some embodiments, the processor 1110 may be further coupled to an extended bus such as a peripheral component interconnection (“PCI”) bus.

The memory device 1120 may store data for operations of the electronic device 1100. For example, the memory device 1120 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, etc., and/or at least one volatile memory device such as a dynamic random access memory (“DRAM”) device, a static random access memory (“SRAM”) device, a mobile dynamic random access memory (“mobile DRAM”) device, etc.

The storage device 1130 may be a solid state drive (“SSD”) device, a hard disk drive (“HDD”) device, a compact disc-read only memory (“CD-ROM”) device, etc. The I/O device 1140 may be an input device such as a keyboard, a keypad, a mouse, a touch screen, etc., and an output device such as a printer, a speaker, etc. The power supply 1150 may supply power for operations of the electronic device 1100. The display device 1160 may be coupled to other components through the buses or other communication links.

In the display device 1160, a first pixel may include a first-first transistor that is turned on to store a first data voltage of a data line in a first capacitor of the first pixel in response to a first signal during a first period of a data writing period, and a second pixel may include a first-second transistor that is turned on to store a second data voltage of the data line in a second capacitor of the second pixel in response to a second signal during a second period of the data writing period. Here, the display device 1160 may include the display panel of FIGS. 1 to 34. Accordingly, in the display device 1160 according to embodiments, a demultiplexing operation may be performed without a demultiplexer circuit, a size of a non-display region of a display panel may be reduced, and power consumption of the display device 1160 may be effectively reduced.

The inventions may be applied any electronic device 1100 including the display device 1160. For example, the inventions may be applied to a mobile phone, a smart phone, a virtual reality (“VR”) device, a television (“TV”) (e.g., a digital TV, a three-dimensional (“3D”) TV, etc.), a wearable electronic device, a personal computer (“PC”) (e.g. a laptop computer, a tablet computer, etc.), a home appliance, a personal digital assistant (“PDA”), a portable multimedia player (“PMP”), a digital camera, a music player, a portable game console, a navigation device, etc.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present invention. Accordingly, all such modifications are intended to be included within the scope of the present invention as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display panel comprising:
a data line;
a first pixel configured to store a first data voltage of the data line in a first capacitor in a first period of a data writing period; and
a second pixel configured to store a second data voltage of the data line in a second capacitor in a second period of the data writing period,
wherein the first pixel includes:
a first-first transistor located in a first path from the data line to the first capacitor, and configured to be turned on in response to a first signal during the first period of the data writing period, and
wherein the second pixel includes:
a first-second transistor located in a second path from the data line to the second capacitor, and configured to be turned on in response to a second signal during the second period of the data writing period.

2. The display panel of claim 1, wherein the first signal and the second signal are a same signal having a first level in the first period of the data writing period and having a second level in the second period of the data writing period, and
wherein the first-first transistor and the first-second transistor have different types from each other.

3. The display panel of claim 1, wherein the first signal has a first level in the first period of the data writing period, and has a second level in the second period of the data writing period,
wherein the second signal has the second level in the first period of the data writing period, and has the first level in the second period of the data writing period, and
wherein the first-first transistor and the first-second transistor have a same type.

4. The display panel of claim 1, wherein the first pixel further includes:
a second-first transistor connected in series with the first-first transistor in the first path, and configured to be turned on in response to a third signal during the data writing period, and
wherein the second pixel further includes:
a second-second transistor connected in series with the first-second transistor in the second path, and configured to be turned on in response to the third signal during the data writing period.

5. The display panel of claim 4, wherein the first signal and the second signal are a same signal, and are shifted by half of one horizontal time from the third signal.

6. The display panel of claim 4, wherein the first signal leads the third signal by half of one horizontal time, and
wherein the second signal lags the third signal by half of one horizontal time.

7. The display panel of claim 1, wherein one of the first pixel and the second pixel further includes:
a second transistor including a gate which receives a third signal, a first terminal connected to the data line, and a second terminal connected to both of the first-first transistor and the first-second transistor, and
wherein the other of the first pixel and the second pixel does not include a transistor corresponding to the second transistor.

8. The display panel of claim 1, wherein the first pixel includes:
the first-first transistor including a gate which receives the first signal, a first terminal, and a second terminal;
a second-first transistor including a gate which receives a third signal, a first terminal connected to the data line, and a second terminal connected to the first terminal of the first-first transistor;
a third-first transistor including a gate connected to the second terminal of the first-first transistor, a first terminal which receives a first power supply voltage, and a second terminal;
the first capacitor including a first electrode connected to the gate of the third-first transistor, and a second electrode connected to the first terminal of the third-first transistor; and
a first light emitting element including an anode connected to the second terminal of the third-first transistor, and a cathode which receives a second power supply voltage, and
wherein the second pixel includes:
the first-second transistor including a gate which receives the second signal, a first terminal, and a second terminal;
the second-second transistor including a gate which receives the third signal, a first terminal connected to the data line, and a second terminal connected to the first terminal of the first-second transistor;
a third-second transistor including a gate connected to the second terminal of the first-second transistor, a first terminal which receives the first power supply voltage, and a second terminal;
the second capacitor including a first electrode connected to the gate of the third-second transistor, and a second electrode connected to the first terminal of the third-second transistor; and
a second light emitting element including an anode connected to the second terminal of the third-second transistor, and a cathode which receives the second power supply voltage.

9. The display panel of claim 8, wherein the first signal and the second signal are a same demultiplexing signal having a first level in the first period of the data writing period and having a second level in the second period of the data writing period,
wherein the third signal is a writing signal having the first level in the data writing period,
wherein the first-first transistor, the second-first transistor, the second-second transistor, the third-first transistor and the third-second transistor are P-type transistors, and
wherein the first-second transistor is an N-type transistor.

10. The display panel of claim 8, wherein the first signal and the second signal are a same demultiplexing signal having a second level in the first period of the data writing period and having a first level in the second period of the data writing period,
wherein the third signal is a writing signal having the second level in the data writing period,
wherein the first-first transistor, the second-first transistor, the second-second transistor, the third-first transistor and the third-second transistor are N-type transistors, and
wherein the first-second transistor is a P-type transistor.

11. The display panel of claim 8, wherein the first signal is a first demultiplexing signal having a first level in the first period of the data writing period and having a second level in the second period of the data writing period,
wherein the second signal is a second demultiplexing signal having the second level in the first period of the data writing period and having the first level in the second period of the data writing period,
wherein the third signal is a writing signal having the first level in the data writing period, and
wherein the first-first transistor, the first-second transistor, the second-first transistor, the second-second transistor, the third-first transistor and the third-second transistor are P-type transistors.

12. The display panel of claim 8, wherein the first signal is a first demultiplexing signal having a second level in the first period of the data writing period and having a first level in the second period of the data writing period,
wherein the second signal is a second demultiplexing signal having the first level in the first period of the data writing period and having the second level in the second period of the data writing period,
wherein the third signal is a writing signal having the second level in the data writing period, and
wherein the first-first transistor, the first-second transistor, the second-first transistor, the second-second transistor, the third-first transistor and the third-second transistor are N-type transistors.

13. The display panel of claim 1, wherein the first pixel includes:
the first-first transistor including a gate which receives the first signal, a first terminal, and a second terminal;
a second-first transistor including a gate which receives a third signal, a first terminal connected to the data line, and a second terminal connected to the first terminal of the first-first transistor;
a third-first transistor including a gate, a first terminal connected to the second terminal of the first-first transistor, and a second terminal;
the first capacitor including a first electrode connected to the gate of the third-first transistor, and a second electrode which receives a first power supply voltage;
a fourth-first transistor including a gate which receives the third signal, a first terminal connected to the second terminal of the third-first transistor, and a second terminal connected to the gate of the third-first transistor;
a fifth-first transistor including a gate which receives a fourth signal, a first terminal connected to the gate of the third-first transistor, and a second terminal which receives an initialization voltage;
a sixth-first transistor including a gate which receives a fifth signal, a first terminal which receives the first power supply voltage, and a second terminal connected to the first terminal of the third-first transistor;
a seventh-first transistor including a gate which receives the fifth signal, a first terminal connected to the second terminal of the third-first transistor, and a second terminal;
an eighth-first transistor including a gate which receives a sixth signal, a first terminal, and a second terminal which receives the initialization voltage; and
a first light emitting element including an anode connected to the second terminal of the seventh-first transistor and the first terminal of the eighth-first transistor, and a cathode which receives a second power supply voltage, and
wherein the second pixel includes:
a first-second transistor including a gate which receives the second signal, a first terminal, and a second terminal;
a second-second transistor including a gate which receives the third signal, a first terminal connected to the data line, and a second terminal connected to the first terminal of the first-second transistor;
a third-second transistor including a gate, a first terminal connected to the second terminal of the first-second transistor, and a second terminal;
the second capacitor including a first electrode connected to the gate of the third-second transistor, and a second electrode which receives the first power supply voltage;
a fourth-second transistor including a gate which receives the third signal, a first terminal connected to the second terminal of the third-second transistor, and a second terminal connected to the gate of the third-second transistor;
a fifth-second transistor including a gate which receives the fourth signal, a first terminal connected to the gate of the third-second transistor, and a second terminal which receives the initialization voltage;
a sixth-second transistor including a gate which receives the fifth signal, a first terminal which receives the first power supply voltage, and a second terminal connected to the first terminal of the third-second transistor;
a seventh-second transistor including a gate which receives the fifth signal, a first terminal connected to the second terminal of the third-second transistor, and a second terminal;
an eighth-second transistor including a gate which receives the sixth signal, a first terminal, and a second terminal which receives the initialization voltage; and
a second light emitting element including an anode connected to the second terminal of the seventh-second transistor and the first terminal of the eighth-second transistor, and a cathode which receives the second power supply voltage.

14. The display panel of claim 13, wherein the third signal is a writing signal, the fourth signal is an initialization signal, the fifth signal is an emission signal, the sixth signal is a bypass signal, and the first signal and the second signal are the bypass signal, and
wherein the first-first transistor and the first-second transistor have different types.

15. The display panel of claim 13, wherein the third signal is a writing signal, the fourth signal is an initialization signal, the fifth signal is an emission signal, the sixth signal is a bypass signal, the first signal is the bypass signal, and the second signal is a bypass signal for a pixel row different from a pixel row including the first and second pixels, and
wherein the first-first transistor and the first-second transistor have a same type.

16. The display panel of claim 13, wherein the third signal is a writing signal, the fourth signal is an initialization signal, the fifth signal is an emission signal, the sixth signal is a bypass signal, the first signal is the bypass signal, and the second signal is an initialization signal for a pixel row different from a pixel row including the first and second pixels, and
wherein the first-first transistor and the first-second transistor have a same type.

17. The display panel of claim 1, wherein the first pixel includes:
the first-first transistor including a gate which receives the first signal, a first terminal connected to the data line, and a second terminal;
a second-first transistor including a gate which receives a third signal, a first terminal connected to the second terminal of the first-first transistor, and a second terminal;
a third-first transistor including a first gate connected to the second terminal of the second-first transistor, a first terminal, a second terminal and a second gate;
the first capacitor including a first electrode connected to the first gate of the third-first transistor, and a second electrode connected to the second terminal and the second gate of the third-first transistor;
a third capacitor including a first electrode which receives a first power supply voltage, and a second electrode connected to the second terminal and the second gate of the third-first transistor;
a fourth-first transistor including a gate which receives a fourth signal, a first terminal which receives a reference voltage, and a second terminal connected to the first gate of the third-first transistor;
a fifth-first transistor including a gate which receives a fifth signal, a first terminal which receives the first power supply voltage, and a second terminal connected to the first terminal of the third-first transistor;
a sixth-first transistor including a gate which receives a sixth signal, a first terminal connected to the second terminal and the second gate of the third-first transistor, and a second terminal;
a seventh-first transistor including a gate which receives a seventh signal, a first terminal, and a second terminal which receives an initialization voltage; and
a first light emitting element including an anode connected to the second terminal of the sixth-first transistor and the first terminal of the seventh-first transistor, and a cathode which receives a second power supply voltage, and
wherein the second pixel includes:
the first-second transistor including a gate which receives the second signal, a first terminal connected to the data line, and a second terminal;
a second-second transistor including a gate which receives the third signal, a first terminal connected to the second terminal of the first-second transistor, and a second terminal;
a third-second transistor including a first gate connected to the second terminal of the second-second transistor, a first terminal, a second terminal and a second gate;
the second capacitor including a first electrode connected to the first gate of the third-second transistor, and a second electrode connected to the second terminal and the second gate of the third-second transistor;
a fourth capacitor including a first electrode which receives the first power supply voltage, and a second electrode connected to the second terminal and the second gate of the third-second transistor;
a fourth-second transistor including a gate which receives the fourth signal, a first terminal which receives the reference voltage, and a second terminal connected to the first gate of the third-second transistor;
a fifth-second transistor including a gate which receives the fifth signal, a first terminal which receives the first power supply voltage, and a second terminal connected to the first terminal of the third-second transistor;
a sixth-second transistor including a gate which receives the sixth signal, a first terminal connected to the second terminal and the second gate of the third-second transistor, and a second terminal;
a seventh-second transistor including a gate which receives the seventh signal, a first terminal, and a second terminal which receives the initialization voltage; and
a second light emitting element including an anode connected to the second terminal of the sixth-second transistor and the first terminal of the seventh-second transistor, and a cathode which receives the second power supply voltage.

18. The display panel of claim 17, wherein the third signal is a writing signal, the fourth signal is a reference signal, the fifth signal is a first emission signal, the sixth signal is a second emission signal, the seventh signal is an initialization signal, and the first signal and the second signal are the initialization signal, and
wherein the first-first transistor and the first-second transistor have different types from each other.

19. The display panel of claim 1, wherein a first light emitting element included in the first pixel and a second light emitting element included in the second pixel are light emitting elements of a same color.

20. The display panel of claim 1, wherein the first pixel includes:
a first pixel circuit including the first capacitor and the first-first transistor, and configured to generate a first driving current based on the first data voltage; and
a first light emitting element connected to the first pixel circuit, and configured to emit light based on the first driving current, and
wherein the second pixel includes:
a second pixel circuit including the second capacitor and the first-second transistor, and configured to generate a second driving current based on the second data voltage; and
a second light emitting element including an anode extension, connected to the second pixel circuit through the anode extension, and configured to emit light based on the second driving current.

21. The display panel of claim 1, wherein the first pixel includes a first pixel circuit located in a first column, and a first red light emitting element located in the first column and a second column,
wherein the second pixel includes a second pixel circuit located in the second column, and a second red light emitting element located in a fourth column and a fifth column,
wherein the display panel further comprises:
a third pixel including a third pixel circuit located in a third column, and a first green light emitting element located in the first column and the second column;
a fourth pixel including a fourth pixel circuit located in the fourth column, and a second green light emitting element located in the fourth column and the fifth column;
a fifth pixel including a fifth pixel circuit located in the fifth column, and a first blue light emitting element located in the second column and the third column; and
a sixth pixel including a sixth pixel circuit located in a sixth column, and a second blue light emitting element located in the fifth column and the sixth column,
wherein the second red light emitting element located in the fourth column and the fifth column is connected to the second pixel circuit located in the second column through an anode extension of the second red light emitting element,
wherein the first green light emitting element located in the first column and the second column is connected to the third pixel circuit located in the third column through an anode extension of the first green light emitting element, and
wherein the first blue light emitting element located in the second column and the third column is connected to the fifth pixel circuit located in the fifth column through an anode extension of the first blue light emitting element.

22. The display panel of claim 21, wherein the data line is a first data line connected to the first pixel circuit and the second pixel circuit, located between the first column and the second column, and transferring the first and second data voltages for the first and second red light emitting elements, and
wherein the display panel further comprises:
a second data line located between the third column and the fourth column, connected to the third pixel circuit and the fourth pixel circuit, and transferring data voltages for the first and second green light emitting elements; and
a third data line located between the fifth column and the sixth column, connected to the fifth pixel circuit and the sixth pixel circuit, and transferring data voltages for the first and second blue light emitting elements.

23. The display panel of claim 1, wherein the first pixel includes a first pixel circuit located in a second column, and a first red light emitting element located in a first column and the second column,
wherein the second pixel includes a second pixel circuit located in a third column, and a second red light emitting element located in a fourth column and a fifth column,
wherein the display panel further comprises:
a third pixel including a third pixel circuit located in the first column, and a first green light emitting element located in the first column and the second column;
a fourth pixel including a fourth pixel circuit located in a sixth column, and a second green light emitting element located in the fourth column and the fifth column;
a fifth pixel including a fifth pixel circuit located in the fourth column, and a first blue light emitting element located in the second column and the third column; and
a sixth pixel including a sixth pixel circuit located in the fifth column, and a second blue light emitting element located in the fifth column and the sixth column,
wherein the second red light emitting element located in the fourth column and the fifth column is connected to the second pixel circuit located in the third column through an anode extension of the second red light emitting element,
wherein the second green light emitting element located in the fourth column and the fifth column is connected to the fourth pixel circuit located in the sixth column through an anode extension of the second green light emitting element, and
wherein the first blue light emitting element located in the second column and the third column is connected to the fifth pixel circuit located in the fourth column through an anode extension of the first blue light emitting element.

24. The display panel of claim 23, wherein the data line is a second data line connected to the first pixel circuit and the second pixel circuit, located between the second column and the third column, and transferring the first and second data voltages for the first and second red light emitting elements, and
wherein the display panel further comprises:
a first data line located adjacent to the first column, connected to the third pixel circuit, and transferring a data voltage for the first green light emitting element;
a third data line located between the fourth column and the fifth column, connected to the fifth pixel circuit and the sixth pixel circuit, and transferring data voltages for the first and second blue light emitting elements; and
a fourth data line located adjacent to the sixth column, connected to the fourth pixel circuit, and transferring a data voltage for the second green light emitting element.

25. The display panel of claim 1, wherein the first pixel includes a first pixel circuit located in a first row and a first column, and a first red light emitting element located in the first row and the first column,
wherein the second pixel includes a second pixel circuit located in the first row and a second column, and a second red light emitting element located in a second row and the second and third columns, and
wherein the display panel further comprises:
a third pixel including a third pixel circuit located in the first row and the third column, and a first blue light emitting element located in the first row and the second and third columns;
a fourth pixel including a fourth pixel circuit located in the first row and a fourth column, and a second blue light emitting element located in the second row and the fourth and fifth columns;
a fifth pixel including a fifth pixel circuit located in the second row and the first column, and a first green light emitting element located in the second row and the first and second columns;
a sixth pixel including a sixth pixel circuit located in the second row and the second column, and a second green light emitting element located in a third row and the first and second columns;
a seventh pixel including a seventh pixel circuit located in the second row and the third column, and a third green light emitting element located in the second row and the third and fourth columns; and
an eighth pixel circuit located in the second row and the fourth column, and a fourth green light emitting element located in the third row and the third and fourth columns.

26. The display panel of claim 25, wherein the data line is a first data line connected to the first, second, fifth and sixth pixel circuits, located between the first column and the second column, transferring the first and second data voltages for the first and second red light emitting elements in the data writing period, and transferring data voltages for the first and second green light emitting elements in a second data writing period after the data writing period, and
wherein the display panel further includes:
a second data line located between the third column and the fourth column, connected to the third, fourth, seventh and eighth pixel circuits, transferring data voltages for the first and second blue light emitting elements in the data writing period, and transferring data voltages for the third and fourth green light emitting elements in the second data writing period.

27. An electronic device comprising:
a display panel; and
a power supply configured to provide power to the display panel,
wherein the display panel comprises:
a first data line;
a second data line;
a first pixel configured to store a first data voltage of the first data line in a first capacitor in a first period of a data writing period; and
a second pixel configured to store a second data voltage of the second data line in a second capacitor in a second period of the data writing period,
wherein the first pixel includes:
a first-first transistor located in a first path from the first data line to the first capacitor, and configured to be turned on in response to a first signal during the first period of the data writing period, and
wherein the second pixel includes:
a first-second transistor located in a second path from the second data line to the second capacitor, and configured to be turned on in response to a second signal during the second period of the data writing period.

28. A display panel comprising:
a data line;
a first pixel configured to store a first data voltage of the data line in a first capacitor in a portion of a data writing period; and
a second pixel configured to store a second data voltage of the data line in a second capacitor in an entire period of the data writing period,
wherein the first pixel includes:
a first transistor located in a path from the data line to the first capacitor, configured to be turned on in response to a first signal during the portion of the data writing period, and configured to be turned off a remaining period of the data writing period.

29. The display panel of claim 28, wherein the first pixel further includes:
a second-first transistor connected in series with the first transistor in the path, and configured to be turned on in response to a second signal during the data writing period, and
wherein the second pixel includes:
a second-second transistor directly connected to the data line, and configured to be turned on in response to the second signal during the data writing period.

30. A display device comprising:
a display panel including a data line, a first pixel configured to store a first data voltage of the data line in a first capacitor in a first period of a data writing period, and a second pixel configured to store a second data voltage of the data line in a second capacitor in a second period of the data writing period;
a scan driver configured to provide a first signal, a second signal and a writing signal having an on-level during the data writing period to the first pixel and the second pixel;
a data driver configured to provide the first data voltage and the second data voltage to the first pixel and the second pixel through the data line; and
a controller configured to control the scan driver and the data driver,
wherein the first pixel includes:
a first-first transistor located in a first path from the data line to the first capacitor, and configured to be turned on in response to the first signal during the first period of the data writing period, and
wherein the second pixel includes:
a first-second transistor located in a second path from the data line to the second capacitor, and configured to be turned on in response to the second signal during the second period of the data writing period.
